(19) United States
(12) Patent Application Publication
(10) Pub. No.: US 2018/0175309 A1
(43) Pub. Date: Jun. 21, 2018

(54) ORGANOMETALLIC COMPOUND AND ORGANIC LIGHT-EMITTING DEVICE EMPLOYING THE SAME

(71) Applicant: INDUSTRIAL TECHNOLOGY RESEARCH INSTITUTE, Hsinchu (TW)

(72) Inventors: Jin-Sheng LIN, Taipei City (TW); Jia-Lun LIOU, Hengshan Township (TW); Yung-Chen CHENG, Xiushui Township (TW); Meng-Hao CHANG, New Taipei City (TW); Chun-Neng KU, Tainan City (TW); Pang-Chi HUANG, Taoyuan City (TW); Mei-Rurng TSENG, Hsinchu City (TW)

(73) Assignee: INDUSTRIAL TECHNOLOGY RESEARCH INSTITUTE, Hsinchu (TW)

(21) Appl. No.: 15/498,838

(22) Filed: Apr. 27, 2017

(30) Foreign Application Priority Data
Dec. 16, 2016 (TW) 105141737

(51) Int. Cl. H01L 51/00; C07F 15/00; C09K 11/06

(52) U.S. Cl. CPC H01L 51/0085; H01L 51/5016; C09K 11/06; C07F 15/0033

(57) ABSTRACT

An organic metal complex is provided. The organic metal complex has the following formula (I):

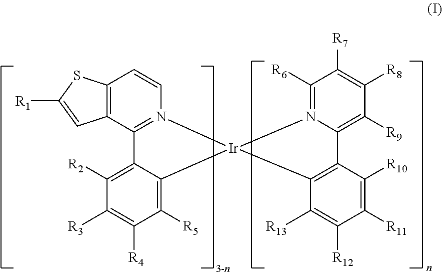

wherein R¹ can be hydrogen, halogen, C₁₋₁₂alkyl group, C₁₋₁₂ alkoxy group, amine, C₂₋₆ alkenyl group, C₂₋₆ alkynyl group, C₅₋₁₀ cycloalkyl group, C₃₋₁₂ heteroaryl group, or C₆₋₁₂ aryl group; R², R³, R⁴, and R⁵ are independently of each other and can be hydrogen, halogen, C₁₋₁₂ alkyl group, C₁₋₁₂ alkoxy group, C₁₋₁₂ fluoroalkyl group, or two adjacent R², R³, R⁴, and R⁵ are optionally combined with the carbon atoms which they are attached to, to form a cycloalkyl group, or aryl group; R⁶-R¹³ are independent and can be hydrogen, halogen, C₁₋₁₂ alkyl group, C₁₋₁₂ fluoroalkyl group, or two adjacent R⁶-R¹³ are optionally combined with the carbon atoms which they are attached to, to form a cycloalkyl group, or aryl group and n is 1 or 2.

### CROSS REFERENCE TO RELATED APPLICATIONS

The application is based on, and claims priority of Taiwan Application Serial Number 105141737, filed on Dec. 16, 2016, the disclosure of which are hereby incorporated by reference herein in their entirety.

### TECHNICAL FIELD

The disclosure relates to an organometallic compound and an organic light-emitting device employing the same.

### BACKGROUND

Organic light-emitting devices are popular in flat panel display due to their high illumination, light weight, self-illumination, low power consumption, simple fabrication, rapid response time, wide viewing angle, and no backlight requirement.

Generally, an organic electroluminescent device is composed of a light-emission layer sandwiched between a pair of electrodes. When an electric field is applied to the electrodes, the cathode injects electrons into the light-emission layer and the anode injects holes into the light-emission layer. When the electrons recombine with the holes in the light-emission layer, excitons are formed. Recombination of the electron and hole results in light emission.

Depending on the spin states of the hole and electron, the exciton, which results from the recombination of the hole and electron, can have either a triplet or singlet spin state. Luminescence from a singlet exciton results in fluorescence whereas luminescence from a triplet exciton results in phosphorescence. The emissive efficiency of phosphorescence is three times that of fluorescence.

Considering the luminescence mechanism of phosphorescent materials in OLED devices, in order to achieve better luminescence efficiency and quantum efficiency, the phosphorescent materials with a proper energy level gap and thermal stability are required. Therefore, the structural design of such phosphorescent materials will be correspondingly difficult.

Therefore, there is a need for a novel phosphorescent material to increase the emissive efficiency of an OLED.

### SUMMARY

According to an embodiment of the disclosure, the disclosure provides an organometallic compound having a structure represented by Formula (I):

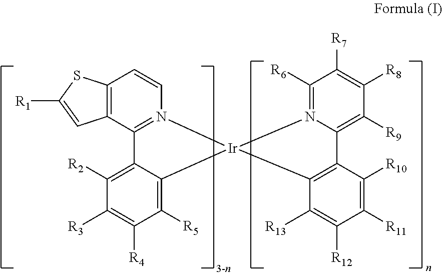

In Formula (I), R₁ is hydrogen, halogen, C₁₋₁₂ alkyl group, C₁₋₁₂ alkoxy group, amine, C₂₋₆ alkenyl group, C₂₋₆ alkynyl group, C₅₋₁₀ cycloalkyl group, C₃₋₁₂ heteroaryl group, or C₆₋₁₂ aryl group; R₂, R₃, R₄, and R₅ are independently of each other and can be hydrogen, halogen, C₁₋₁₂ alkyl group, C₁₋₁₂ alkoxy group, C₁₋₁₂ fluoroalkyl group, or two adjacent groups of R₂, R₃, R₄, and R₅ are optionally combined with the carbon atoms which they are attached to, to form a cycloalkyl group, or aryl group; R₆-R₁₃ are independent and can be hydrogen, halogen, C₁₋₁₂ alkyl group, C₁₋₁₂ fluoroalkyl group, or two adjacent groups of R₆-R₁₃ are optionally combined with the carbon atoms which they are attached to, to form a cycloalkyl group, or aryl group; and n is 1 or 2.

According to another embodiment of the disclosure, the disclosure provides an organic light-emitting device. The device includes an anode, a cathode and an organic light-emitting element disposed between the anode and the cathode. The organic light-emitting element includes the aforementioned organometallic compound.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 shows a cross section of an organic light-emitting device disclosed by an embodiment of the disclosure.

### DETAILED DESCRIPTION

The following description is of the best-contemplated mode of carrying out the disclosure. This description is made for the purpose of illustrating the general principles of the disclosure and should not be taken in a limiting sense. The scope of the disclosure is best determined by reference to the appended claims.

According to an embodiment of the disclosure, the disclosure provides an organometallic compound having a structure represented by the following Formula (I):

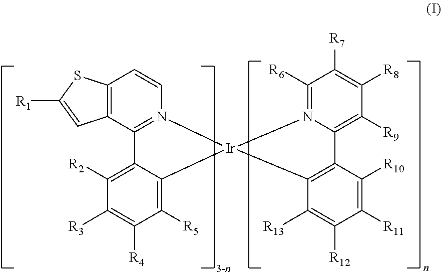

In Formula (I), R₁ can be hydrogen, methyl, ethyl, propyl, isopropyl, n-butyl, isobutyl, tert-butyl, pentyl, hexyl, cyclohexyl, a substituted or unsubstituted phenyl group, a substituted or unsubstituted biphenyl group, a substituted or unsubstituted naphthyl group, a substituted or unsubstituted pyridyl group, a substituted or unsubstituted furyl group, a substituted or unsubstituted carbazole group, a substituted or unsubstituted anthryl group, a substituted or unsubstituted phenanthrenyl group, a substituted or unsubstituted imidazolyl group, a substituted or unsubstituted pyrimidinyl group, a substituted or unsubstituted quinolinyl group, a substituted or unsubstituted indolyl group, or a substituted or unsubstituted thiazolyl group.

For example, R₁ can be

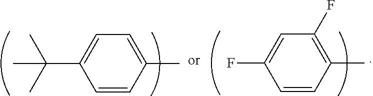

In Formula (I), R₂, R₃, R₄ and R₅ are independently of each other, and can be hydrogen, fluoro, methyl, ethyl, propyl, isopropyl, n-butyl, isobutyl, tert-butyl, pentyl, hexyl, fluoromethyl group, fluoroethyl group, fluoropropyl group, or two adjacent groups of R₂, R₃, R₄, and R₅ are optionally combined with the carbon atoms which they are attached to, to form a phenyl group. R₆-R₁₃ are independent and can be hydrogen, fluoro, methyl, ethyl, propyl, isopropyl, n-butyl, isobutyl, tert-butyl, pentyl, hexyl, fluoromethyl group, fluoroethyl group, fluoropropyl group, or two adjacent groups of R₇-R₁₂ are optionally combined with the carbon atoms which they are attached to, to form a phenyl group.

According to some embodiments of the disclosure, the organometallic compound can be

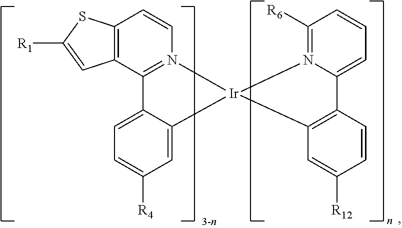

R₁ can be hydrogen, halogen, C₁₋₁₂ alkyl group, C₁₋₁₂ alkoxy group, or a substituted or unsubstituted phenyl group; R₄, R₆ and R₁₂ are independently of each other and can be hydrogen, or C₁₋₁₂ alkyl group; and n can be 1 or 2.

According to some embodiments of the disclosure, the organometallic compound can be

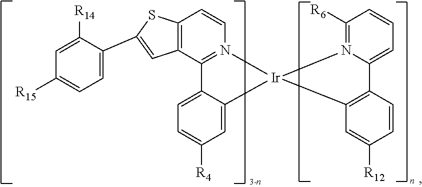

R₁₄ and R₁₅ are independently of each other and can be hydrogen, halogen, or C₁₋₁₂ alkyl group, R₄, R₆ and R₁₂ are independent and can be hydrogen, or C₁₋₁₂ alkyl group; and n can be 1 or 2.

The organometallic compounds according to Formula (I) of the disclosure include the compounds shown in Table 1.

TABLE 1

| Example | Structure |
|---|---|
| 1 | 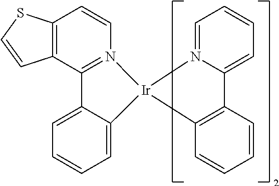 |
| 2 | 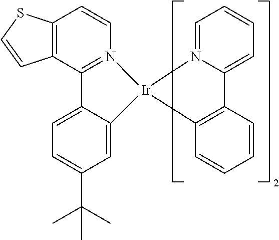 |
| 3 | 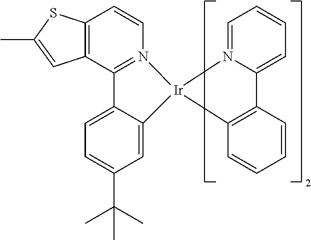 |
| 4 | 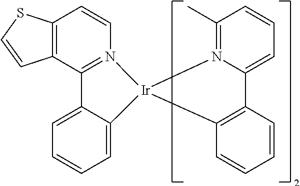 |
| 5 | 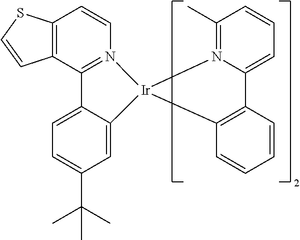 |
| 6 | 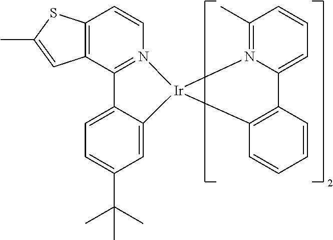 |
| 7 | 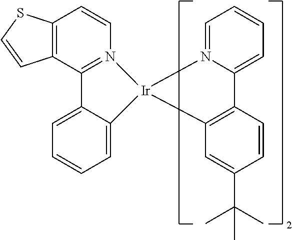 |
| 8 | 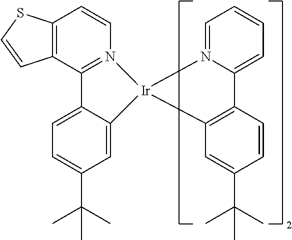 |
| 9 | 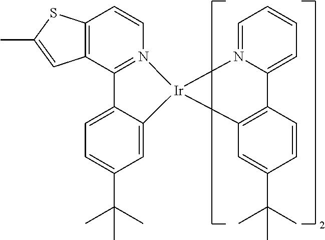 |
| 10 | 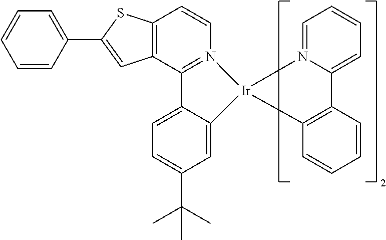 |
| 11 | 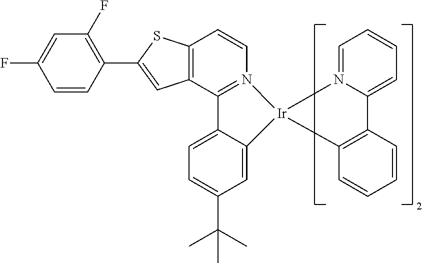 |
| 12 | 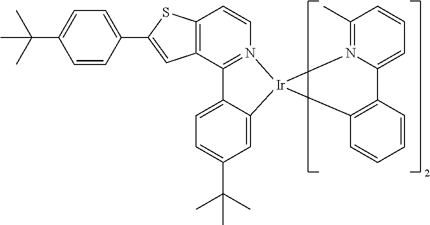 |
| 13 | 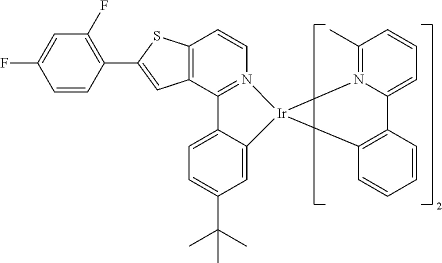 |
| 14 | 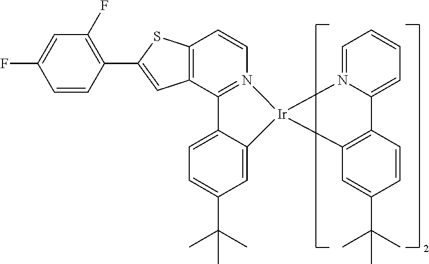 |
| 15 | 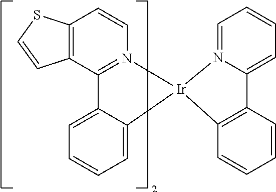 |
| 16 | 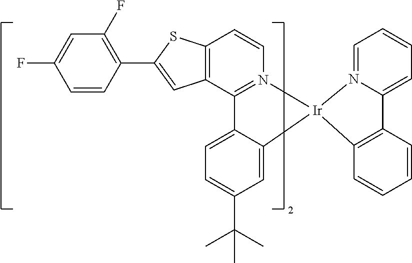 |

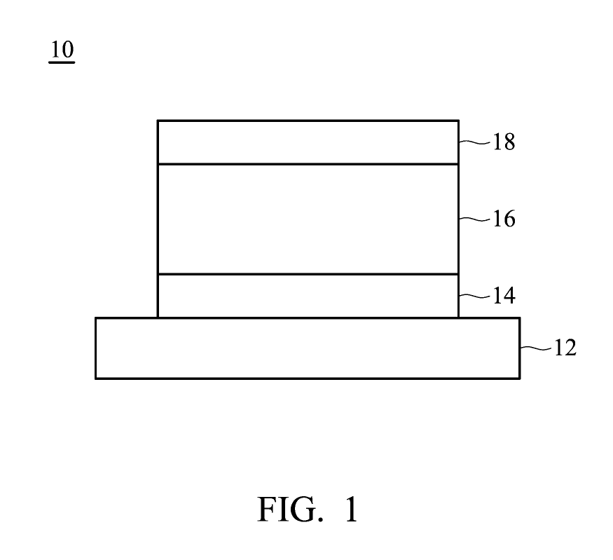

FIG. 1 shows an embodiment of an organic light-emitting device 10. The organic light-emitting device 10 includes a substrate 12, a bottom electrode 14, an organic light-emitting element 16, and a top electrode 18, as shown in FIG. 1. The organic light-emitting device can be a top-emission, bottom-emission, or dual-emission device. The substrate 12 can be a glass, plastic, or semiconductor substrate. Suitable materials for the bottom and top electrodes can be Ca, Ag, Mg, A, Li, In, Au, Ni, W, Pt, Cu, indium tin oxide (ITO), indium zinc oxide (IZO), aluminum zinc oxide (AZO), or zinc oxide (ZnO), formed by sputtering, electron beam evaporation, thermal evaporation, or chemical vapor deposition. Furthermore, at least one of the bottom and top electrodes 14 and 18 is transparent.

The organic light-emitting element 16 at least includes an emission layer, and can further include a hole injection layer, a hole transport layer, an electron transport layer, and an electron injection layer. In an embodiment of the disclosure, at least one layer of the organic light-emitting element 16 includes an organometallic compound having a structure of Formula (I) of the disclosure.

According to another embodiment of the disclosure, the organic light-emitting device can be a phosphorescent organic light-emitting device, and the emission layer of the organic light-emitting element can include a host material and a dopant, wherein the dopant can include an organometallic compound having a structure of Formula (I) of the disclosure. The dose of the dopant is not limited and can be optionally modified by a person of ordinary skill in the field.

The following examples are intended to illustrate the disclosure more fully without limiting the scope, since numerous modifications and variations will be apparent to those skilled in this art.

### Example 1: Preparation of Organometallic Compound A

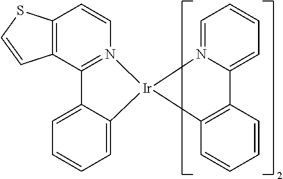

70.9 mmol of 2-(2-aminoethyl)thiophene and 40 ml of water were added into a reaction bottle. Next, 11 mL of benzoyl chloride (94.7 mmol) and 45 mL of sodium hydroxide aqueous solution (20%) were dropwisely added into the reaction bottle at 0° C. and subjected to reaction for 12 hours. Then, the mixture was filtrated. The filter cake was collected, washed with water and hexane, and dried, yielding a white solid. Compound I was obtained with a yield of 80%. The synthesis pathway of the above reaction was as follows:

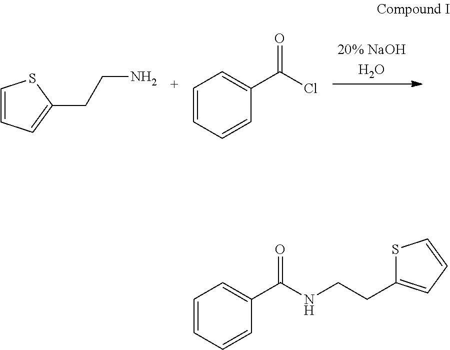 [SMILES: NCCc1cccs1 ; O=C(Cl)c1ccccc1 ; O=C(NCCc1cccs1)c1ccccc1]

Phosphorus oxychloride (POCl₃, 75 mmol) was dropwisely added at 0° C. to a stirred solution of Compound I (50 mmol) in toluene (50 ml). The reaction was then heated to reflux for 2 hrs (After stopping the stirring, the phase separation occurred. The upper layer was brown liquid and the lower layer was black liquid). After cooling to about 40° C., the reaction mixture was neutralized with saturated sodium hydrogen carbonate (NaHCO₃) aqueous solution, and then the mixture was extracted with ethyl acetate (EA) and water. Next, an organic phase was separated and concentrated, and then purified by column chromatography ((SiO₂, EA/Hexane=1/20). Finally, the result was concentrated and then washed with hexane to form a crystal of 99% purity, obtaining Compound II with a yield of 75%. The synthesis pathway of the above reaction was as follows:

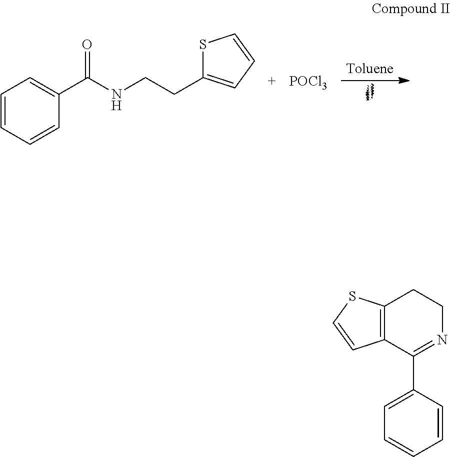

Next, 50 mmol of Compound II was dissolved in 100 ml of toluene. After cooling at 0° C., 10 g of palladium 10% on carbon (Pd/C catalyst) was added into the reaction bottle, and was heated to reflux for 2 hrs (using thin layer chromatography (TLC: SiO₂) to confirm completion of the reaction). Next, after removing Pd/C catalyst by filtration, the filtrate was extracted three times using ethyl acetate (EA) and water as the extraction solvent, and an organic phase was separated and concentrated, and then purified by column chromatography ((SiO₂, EA/Hexane=1/20). Finally, the result was concentrated and then washed with hexane to form a crystal of 99% purity, obtaining Compound III with a yield of 95%. The synthesis pathway of the above reaction was as follows:

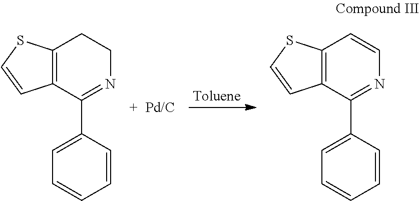 [SMILES: c1ccc(C2=NCCc3sccc32)cc1 ; c1ccc(-c2nccc3sccc23)cc1]

Next, 21 mmol of Phenylpyridine, and 10 mmol of iridium trichloride (IrCl₃), 75 ml of 2-methoxyethanol, and 25 ml of water were added into the reaction bottle. After removing moisture and purging nitrogen gas several times, the reaction bottle was heated to reflux under a nitrogen atmosphere and kept reacting for 24 hrs. After cooling to room temperature, water was added into the reaction mixture to produce precipitate. Then, the precipitate was filtrated. The filter cake was collected, washed with water and n-hexane, and dried, obtaining Dimer-A. The synthesis pathway of the above reaction was as follows:

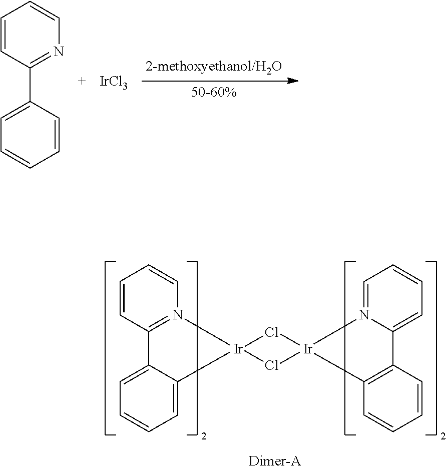

Next, 28.6 mmol of silver trifluoromethane sulfonate (AgOTf) was dissolved in 143 mL of methanol, obtaining an AgOTf-methanol solution. Then, to a stirred solution of 13 mmol of Dimer-A in 130 mL of dichloromethane was added the AgOTf-methanol solution via syringe under nitrogen, and the mixture was continuously stirred for 12 hrs at room temperature. After filtrating for removing sliver chloride and followed by concentrating, Salt-A was obtained. The synthesis pathway of the above reaction was as follows:

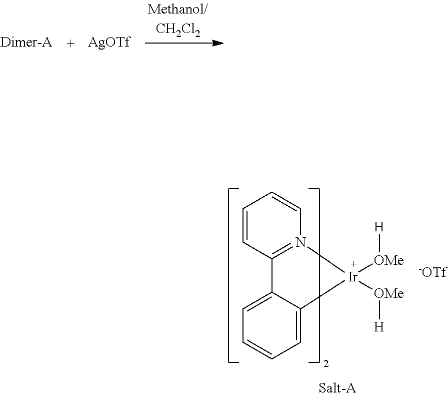

Next, 1 mmol of Salt-A, 1.5 mmol of Compound III, 5 ml of methanol, and 5 ml of ethanol were added into a reaction bottle. After removing moisture and purging nitrogen gas several times, the reaction bottle was heated to 90° C. After reacting for 12 hrs and cooling down to room temperature, the result was extracted three times using dichloromethane and water as the extraction solvent, and an organic phase was separated and concentrated, and then purified by column chromatography ((SiO₂, EA/Hexane=1/20), obtaining Organometallic compound A with a yield of 21%. The synthesis pathway of the above reaction was as follows:

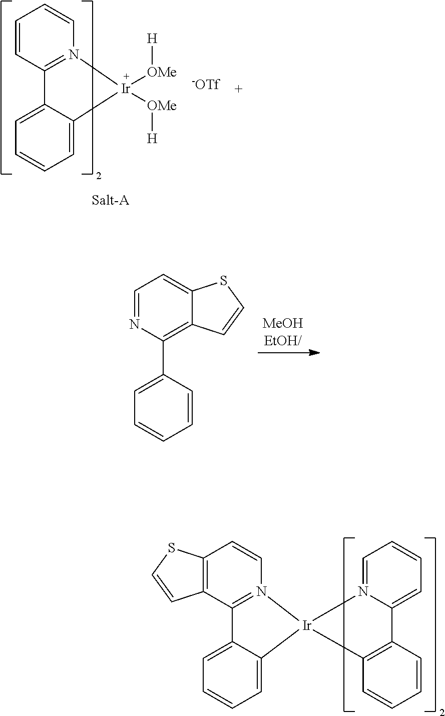

The physical measurement of the Compound A is listed below: ¹H-NMR (500 MHz, CDCl₃, 294 K): 8.34 (d, 1H), 8.20 (d, 1H), 7.88 (t, 2H), 7.65 (d, 2H), 7.61˜7.52 (m, 3H), 7.44 (d, 1H), 7.42 (d, 1H), 7.37 (d, 1H), 7.33 (d, 1H), 7.00˜6.79 (m, 11H)∘

### Example 2: Preparation of Organometallic Compound B

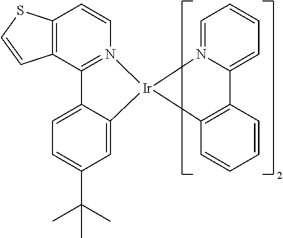

70.9 Mmol of 2-(2-aminoethyl)thiophene and 40 ml of water were added into a reaction bottle. Next, 11 mL of benzoyl chloride (94.7 mmol) and 45 mL of sodium hydroxide aqueous solution (20%) were dropwisely added into the reaction bottle at 0° C. and subjected to reaction for 12 hours. Then, the mixture was filtrated. The filter cake was collected, washed with water and hexane, and dried, yielding a white solid. Compound IV was obtained with a yield of 80%. The synthesis pathway of the above reaction was as follows:

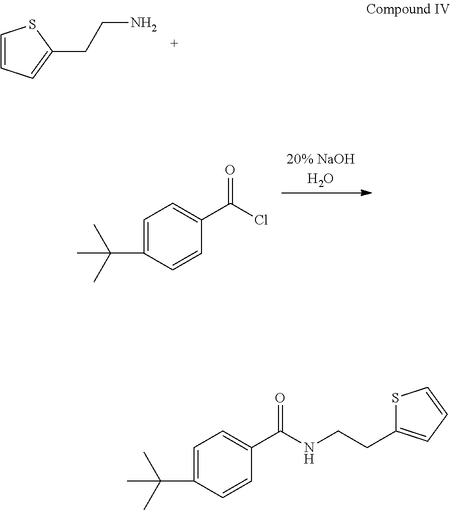 [SMILES: NCCc1cccs1 ; CC(C)(C)c1ccc(C(=O)Cl)cc1 ; CC(C)(C)c1ccc(C(=O)NCCc2cccs2)cc1]

Phosphorus oxychloride (POCl₃, 75 mmol) was dropwisely added at 0° C. to a stirred solution of Compound IV (50 mmol) in toluene (50 ml). The reaction was then heated to reflux for 2 hrs (After stopping the stirring, the phase separation occurred. The upper layer was brown liquid and the lower layer was black liquid). After cooling to about 40° C., the reaction mixture was neutralized with saturated sodium hydrogen carbonate (NaHCO₃) aqueous solution, and then the mixture was extracted with ethyl acetate (EA) and water. Next, an organic phase was separated and concentrated, and then purified by column chromatography ((SiO₂, EA/Hexane=1/20). Finally, the result was concentrated and then washed with hexane to form a crystal of 99% purity, obtaining Compound V with a yield of 72%. The synthesis pathway of the above reaction was as follows:

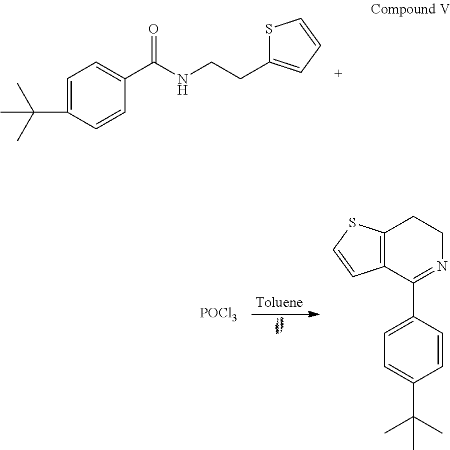 [SMILES: CC(C)(C)c1ccc(C(=O)NCCc2cccs2)cc1 ; "POCl3" ; CC(C)(C)c1ccc(C2=NCCc3sccc32)cc1]

To a stirred solution of Compound V (50 mmol) in toluene (100 ml) was added palladium 10% on carbon (Pd/C catalyst, 10 g) at 0° C. The reaction was heated to reflux for 2 hrs (using thin layer chromatography (TLC: SiO₂) to confirm completion of the reaction). Next, after removing Pd/C catalyst by filtration, the filtrate was extracted three times using ethyl acetate (EA) and water as the extraction solvent, and an organic phase was separated and concentrated, and then purified by column chromatography ((SiO₂, EA/Hexane=1/20). Finally, the result was concentrated and then washed with hexane to form a crystal of 99% purity, obtaining Compound VI with a yield of 96%. The synthesis pathway of the above reaction was as follows:

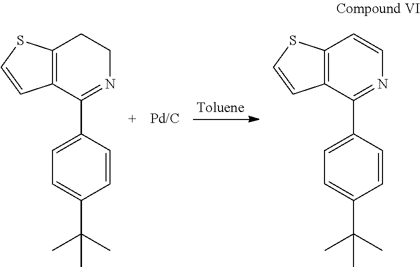 [SMILES: CC(C)(C)c1ccc(C2=NCCc3sccc32)cc1 ; CC(C)(C)c1ccc(-c2nccc3sccc23)cc1]

Next, 1 mmol of Salt-A, 1.5 mmol of Compound VI, 5 ml of methanol, and 5 ml of ethanol were added into a reaction bottle. Next, after removing moisture and purging nitrogen gas several times, the reaction bottle was heated to 90° C. After reacting for 12 hrs and cooling down to room temperature, the result was extracted three times using dichloromethane and water as the extraction solvent, and the combined organic phase was separated and concentrated, and then purified by column chromatography ((SiO₂, EA/Hexane=1/20), obtaining Organometallic compound B with a yield of 25%. The synthesis pathway of the above reaction was as follows:

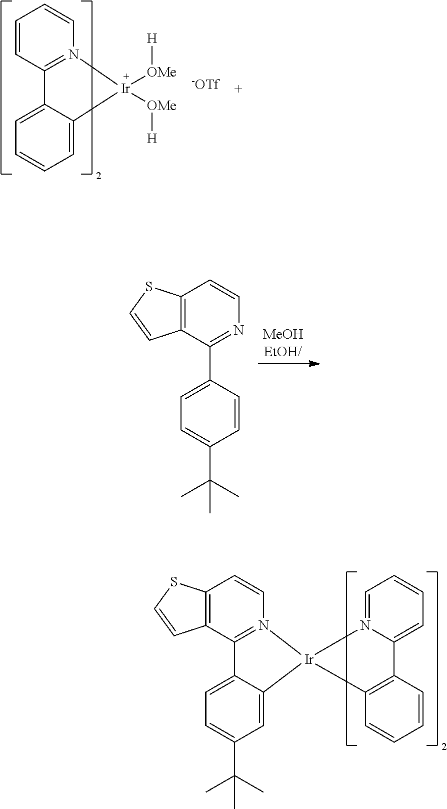

The physical measurement of the Compound B is listed below: ¹H-NMR (500 MHz, CDCl₃, 294 K): 8.30 (d, 1H), 8.09 (d, 1H), 7.89 (d, 1H), 7.85 (d, 1H), 7.64 (t, 2H), 7.60˜7.53 (m, 4H), 7.44˜7.41 (m, 2H), 7.31 (d, 1H), 7.01˜6.98 (m, 2H), 6.91˜6.85 (m, 51H), 6.82˜5.30 (m, 3H), 1.10 (s, 9H)∘

### Example 3: Preparation of Organometallic Compound C

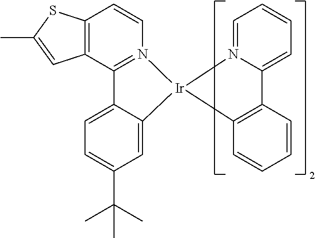

70.9 Mmol of 2-(2-aminoethyl)-5-methylthiophene and 40 ml of water were added into a reaction bottle. Next, 11 mL of 4-tert-Butylbenzoyl chloride (94.7 mmolM) and 45 mL of sodium hydroxide aqueous solution (20%) were dropwisely added into the reaction bottle at 0° C. and subjected to reaction for 12 hours. Then, the mixture was filtrated. The filter cake was collected, washed with water and hexane, and dried, yielding a white solid. Compound VII was obtained with a yield of 80%. The synthesis pathway of the above reaction was as follows:

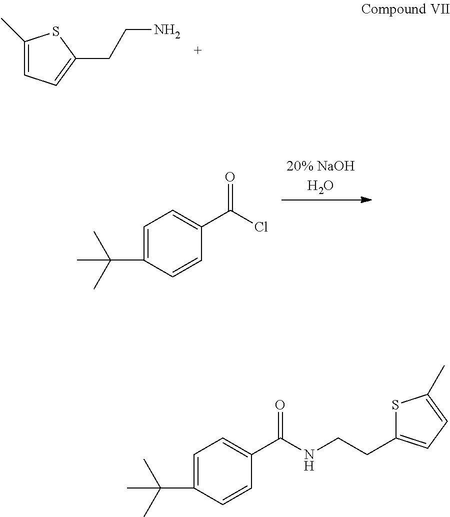

Phosphorus oxychloride (POCl₃, 75 mmol) was dropwisely added at 0° C. to a stirred solution of Compound VII (50 mmol) in toluene (50 ml). The reaction was then heated to reflux for 2 hrs (After stopping the stirring, the phase separation occurred. The upper layer was brown liquid and the lower layer was black liquid). After cooling to about 40° C., the reaction mixture was neutralized with saturated sodium hydrogen carbonate (NaHCO₃) aqueous solution, and then the mixture was extracted with ethyl acetate (EA) and water. Next, an organic phase was separated and concentrated, and then purified by column chromatography ((SiO₂, EA/Hexane=1/20). Finally, the result was concentrated and then washed with hexane to form a crystal of 99% purity, obtaining Compound VIII with a yield of 70%. The synthesis pathway of the above reaction was as follows:

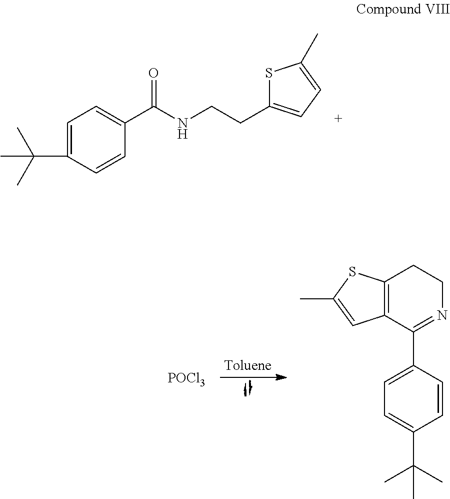 [SMILES: Cc1ccc(CCNC(=O)c2ccc(C(C)(C)C)cc2)s1 ; "POCl3" ; Cc1cc2c(s1)CCN=C2c1ccc(C(C)(C)C)cc1]

To a stirred solution of Compound VIII (50 mmol) in toluene (100 ml) was added palladium 10% on carbon (Pd/C catalyst, 10 g) at 0° C. The reaction was heated to reflux for 2 hrs (using thin layer chromatography (TLC: SiO₂) to confirm completion of the reaction). Next, after removing Pd/C catalyst by filtration, the filtrate was extracted three times using ethyl acetate (EA) and water as the extraction solvent, and an organic phase was separated and concentrated, and then purified by column chromatography ((SiO₂, EA/Hexane=1/20). Finally, the result was concentrated and then washed with hexane to form a crystal of 99% purity, obtaining Compound IX with a yield of 92%. The synthesis pathway of the above reaction was as follows:

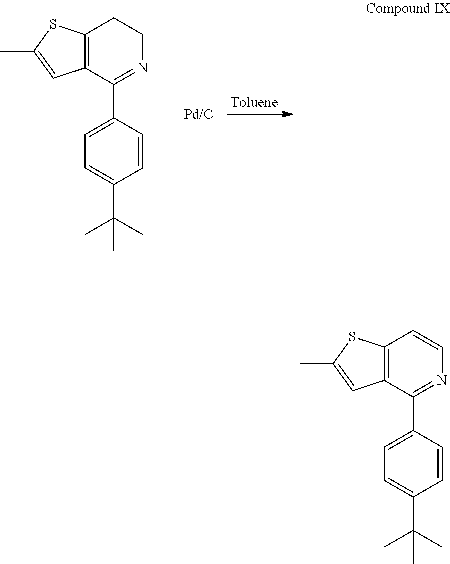 [SMILES: Cc1cc2c(s1)CCN=C2c1ccc(C(C)(C)C)cc1 ; Cc1cc2c(-c3ccc(C(C)(C)C)cc3)nccc2s1]

Next, 1 mmol of Salt-A, 1.5 mmol of Compound IX, 5 ml of methanol, and 5 ml of ethanol were added into a reaction bottle. Next, after removing moisture and purging nitrogen gas several times, the reaction bottle was heated to 90° C. After reacting for 12 hrs and cooling down to room temperature, the result was extracted three times using dichloromethane and water as the extraction solvent, and the combined organic phase was separated and concentrated, and then purified by column chromatography ((SiO₂, EA/Hexane=1/20), obtaining Organometallic compound C with a yield of 24%. The synthesis pathway of the above reaction was as follows:

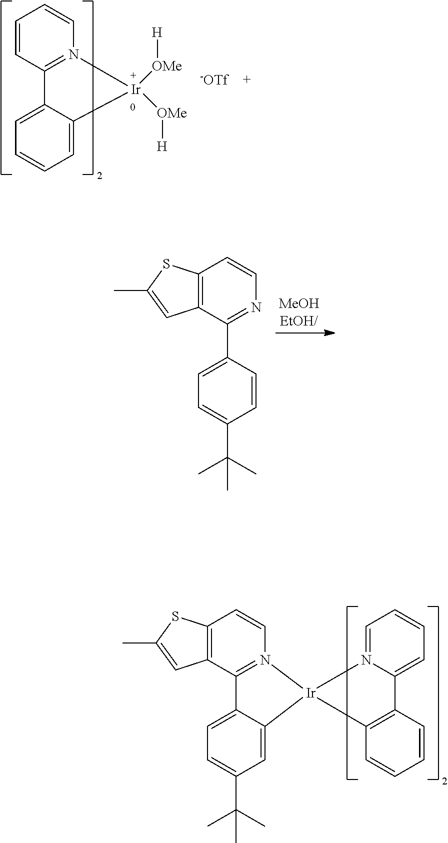

The physical measurement of the Compound C is listed below: ¹H-NMR (500 MHz, CDCl₃, 294 K): 8.11 (d, 1H), 7.93 (s, 1H), 7.86 (t, 2H), 7.71 (d, 1H), 6.67 (d, 1H), 7.57˜7.47 (m, 3H), 7.36 (d, 1H), 7.26 (d, 1H), 7.09 (d, 1H), 6.93 (t, 2H), 6.83˜6.74 (m, 5H), 6.63 (s, 2H), 6.49 (d, 1H), 2.69 (s, 3H), 1.10 (s, 9H).

### Example 4: Preparation of Organometallic Compound D

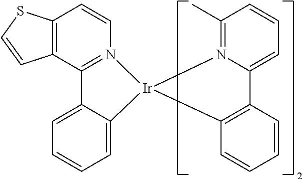

Next, 21 mmol of 2-methyl-6-phenylpyridine, and 10 mmol of iridium trichloride (IrCl₃), 75 ml of 2-methoxyethanol, and 25 ml of water were added into the reaction bottle. After removing moisture and purging nitrogen gas several times, the reaction bottle was heated to reflux under a nitrogen atmosphere and kept reacting for 24 hrs. After cooling to room temperature, water was added into the reaction mixture to produce precipitate. Then, the precipitate was filtrated. The filter cake was collected, washed with water and n-hexane, and dried, obtaining Dimer-B. The synthesis pathway of the above reaction was as follows:

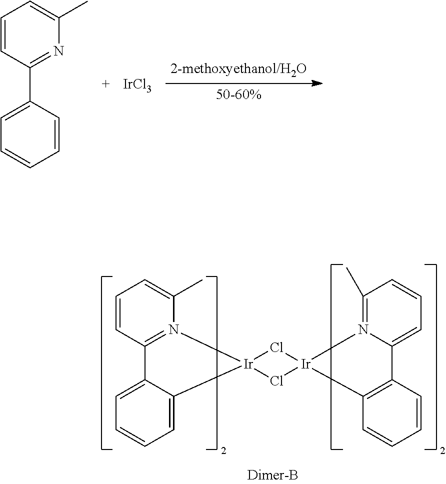

Next, 2.73 mmol of silver trifluoromethane sulfonate (AgOTf) was dissolved in 14 mL of methanol, obtaining an AgOTf-methanol solution. Then, to a stirred solution of 1.24 mmol of Dimer-B in 12 mL of dichloromethane was added the AgOTf-methanol solution via syringe under nitrogen, and the mixture was stirred for 12 hrs at room temperature. After filtrating for removing sliver chloride and followed by concentrating, Salt-B was obtained. The synthesis pathway of the above reaction was as follows:

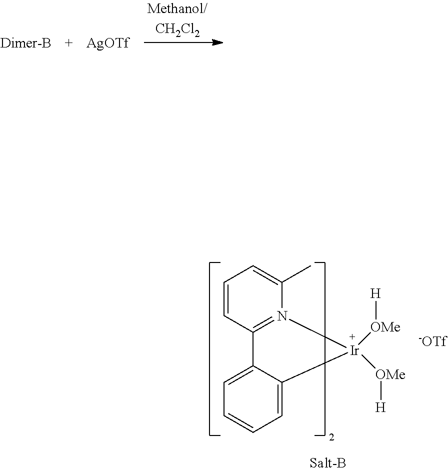

Next, 1 mmol of Salt-B, 1.5 mmol of Compound m, 5 ml of methanol, and 5 ml of ethanol were added into a reaction bottle. Next, after removing moisture and purging nitrogen gas several times, the reaction bottle was heated to 90° C. After reacting for 12 hrs and cooling down to room temperature, the result was extracted three times using dichloromethane and water as the extraction solvent, and the combined organic phase was separated and concentrated, and then purified by column chromatography ((SiO₂, EA/Hexane=1/20), obtaining Organometallic compound D with a yield of 43%. The synthesis pathway of the above reaction was as follows:

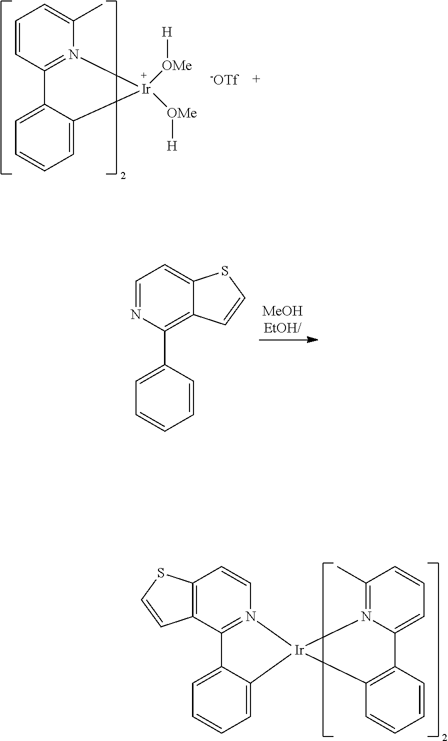

The physical measurement of the Compound D is listed below: ¹H-NMR (500 MHz, CDCl₃, 294 K): 8.30 (d, 1H), 8.14 (d, 1H), 7.84 (d, 1H), 7.80 (d, 1H), 7.72 (d, 1H), 7.69 (d, 1H), 7.57˜7.52 (m, 3H), 7.44 (t, 1H), 7.29 (d, 1H), 6.97˜6.88 (m, 3H), 6.80˜6.68 (m, 5H), 6.62 (t, 1H), 6.54 (d, 1H), 6.47 (d, 1H), 2.02 (s, 3H), 1.89 (s, 3H).

### Example 5: Preparation of Organometallic Compound E

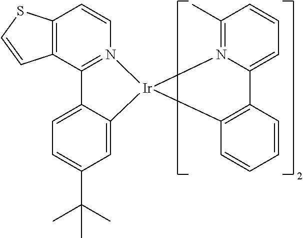

Next, 1 mmol of Salt-B, 1.5 mmol of Compound VI, 5 ml of methanol, and 5 ml of ethanol were added into a reaction bottle. Next, after removing moisture and purging nitrogen gas several times, the reaction bottle was heated to 90° C. After reacting for 12 hrs and cooling down to room temperature, the result was extracted three times using dichloromethane and water as the extraction solvent, and the combined organic phase was separated and concentrated, and then purified by column chromatography ((SiO₂, EA/Hexane=1/20), obtaining Organometallic compound E with a yield of 48%. The synthesis pathway of the above reaction was as follows:

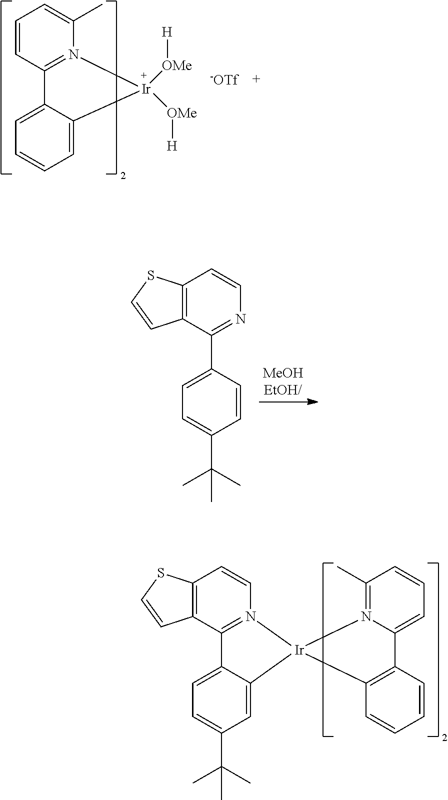

The physical measurement of the Compound E is listed below: ¹H-NMR (500 MHz, CDCl₃, 294 K): 8.25 (d, 1H), 8.00 (d, 1H), 7.83 (d, 2H), 7.73 (d, 1H), 7.61˜7.51 (m, 4H), 7.40 (t, 1H), 7.24 (d, 1H), 6.94˜6.89 (m, 3H), 6.78 (t, 1H), 6.75˜6.72 (m, 2H), 6.65 (d, 1H), 6.62˜6.57 (m, 2H), 6.52 (d, 1H), 2.05 (s, 3H), 1.88 (s, 3H), 1.01 (s, 9H).

### Example 6: Preparation of Organometallic Compound F

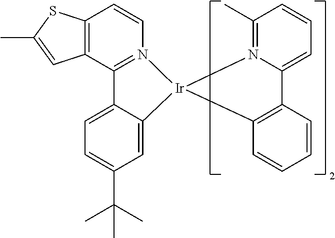

Next, 1 mmol of Salt-B, 1.5 mmol of Compound IX, 5 ml of methanol, and 5 ml of ethanol were added into a reaction bottle. Next, after removing moisture and purging nitrogen gas several times, the reaction bottle was heated to 90° C. After reacting for 12 hrs and cooling down to room temperature, the result was extracted three times using dichloromethane and water as the extraction solvent, and the combined organic phase was separated and concentrated, and then purified by column chromatography ((SiO₂, EA/Hexane=1/20), obtaining Organometallic compound F with a yield of 52%. The synthesis pathway of the above reaction was as follows:

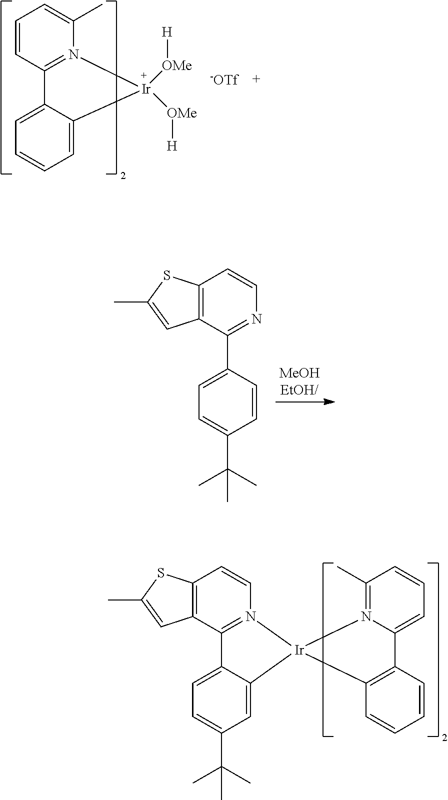

The physical measurement of the Compound F is listed below: ¹H-NMR (500 MHz, CDCl₃, 294 K): 7.95 (d, 1H), 7.88 (s, 1H), 7.82 (d, 2H), 7.73 (d, 1H), 7.58˜7.52 (m, 3H), 7.39 (t, 1H), 7.11 (d, 1H), 6.93˜6.87 (m, 3H), 6.80 (t, 1H), 6.72 (t, 1H), 6.70 (d, 1H), 6.65 (d, 1H), 6.62˜6.57 (m, 2H), 6.52 (d, 1H), 2.64 (s, 3H), 2.04 (s. 3H), 1.89 (s, 3H), 1.01 (s, 9H)∘

### Example 7: Preparation of Organometallic Compound G

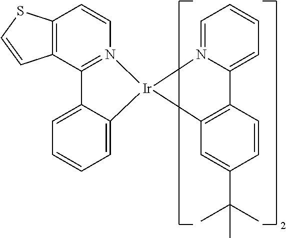

Next, 21 mmol of 2-(4-tert-butylphenyl)pyridine, and 10 mmol of iridium trichloride (IrCl₃), 75 ml of 2-methoxyethanol, and 25 ml of water were added into the reaction bottle. After removing moisture and purging nitrogen gas several times, the reaction bottle was heated to reflux under a nitrogen atmosphere and kept reacting for 24 hrs. After cooling to room temperature, water was added into the reaction mixture to produce precipitate. Then, the precipitate was filtrated. The filter cake was collected, washed with water and n-hexane, and dried, obtaining Dimer-C. The synthesis pathway of the above reaction was as follows:

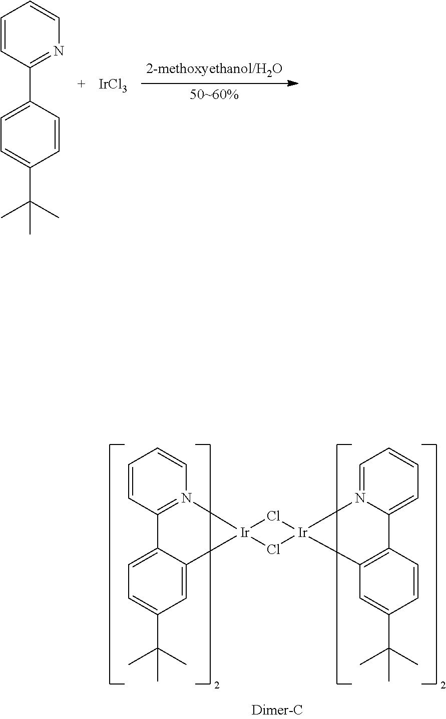

Next, 2.2 mmol of silver trifluoromethane sulfonate (AgOTf) was dissolved in 11 mL of methanol, obtaining an AgOTf-methanol solution. Then, to a stirred solution of 1 mmol of Dimer-C in 10 mL of dichloromethane was added the AgOTf-methanol solution via syringe under nitrogen, and the mixture was stirred for 12 hrs at room temperature. After filtrating for removing sliver chloride and followed by concentrating, Salt-C was obtained. The synthesis pathway of the above reaction was as follows:

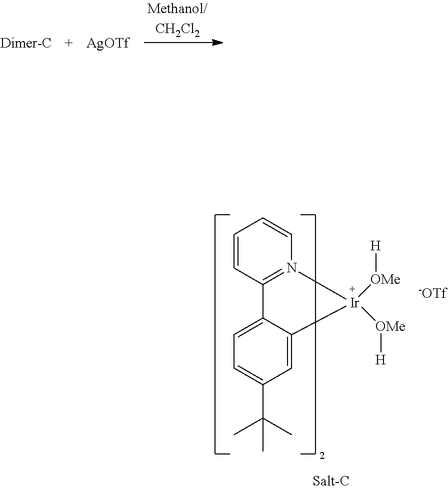

Next, 1 mmol of Salt-C, 1.5 mmol of Compound III, 5 ml of methanol, and 5 ml of ethanol were added into a reaction bottle. Next, after removing moisture and purging nitrogen gas several times, the reaction bottle was heated to 90° C. After reacting for 12 hrs and cooling down to room temperature, the result was extracted three times using dichloromethane and water as the extraction solvent, and the combined organic phase was separated and concentrated, and then purified by column chromatography ((SiO₂, EA/Hexane=1/20), obtaining Organometallic compound G with a yield of 42%. The synthesis pathway of the above reaction was as follows:

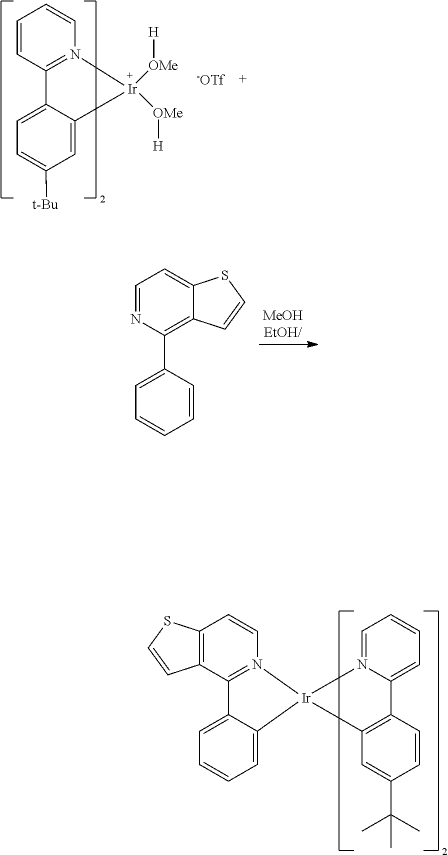

The physical measurement of the Compound G is listed below: ¹H-NMR (500 MHz, CDCl₃, 294 K): 8.31 (d, 1H), 8.16 (d, 1H), 7.79 (d, 2H), 7.57˜7.47 (m, 7H), 7.36˜7.34 (m, 2H), 7.01 (d, 1H), 6.96 (t, 1H), 6.92˜6.88 (m, 3H), 6.87˜6.75 (m, 3H), 6.74 (t, 1H), 1.08 (s, 18H).

### Example 8: Preparation of Organometallic Compound H

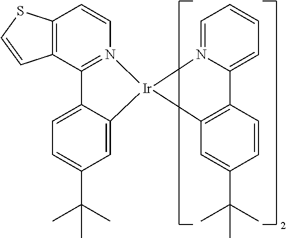

Next, 1 mmol of Salt-C, 1.5 mmol of Compound VI, 5 ml of methanol, and 5 ml of ethanol were added into a reaction bottle. Next, after removing moisture and purging nitrogen gas several times, the reaction bottle was heated to 90° C. After reacting for 12 hrs and cooling down to room temperature, the result was extracted three times using dichloromethane and water as the extraction solvent, and the combined organic phase was separated and concentrated, and then purified by column chromatography ((SiO₂, EA/Hexane=1/20), obtaining Organometallic compound H with a yield of 45%. The synthesis pathway of the above reaction was as follows:

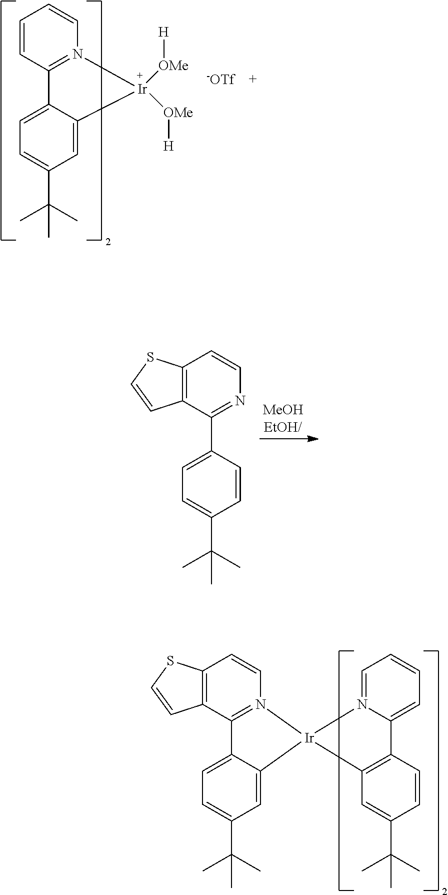

The physical measurement of the Compound H is listed below: ¹H-NMR (500 MHz, CDCl₃, 294 K): 8.26 (d, 1H), 8.05 (d, 1H), 7.75 (t, 2H), 7.54˜7.43 (m, 7H), 7.35 (d, 1H), 7.27 (d, 1H), 7.03 (s, 1H), 6.98 (d, 1H), 6.91˜6.87 (m, 3H), 6.81˜6.78 (m, 2H), 6.72 (t, 1H), 1.13 (s, 9H), 1.08 (s, 9H), 1.07 (s, 9H).

### Example 9: Preparation of Organometallic Compound I

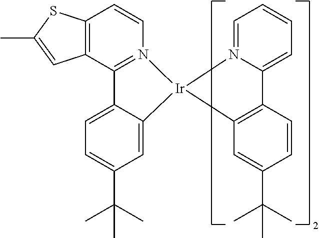

Next, 1 mmol of Salt-C, 1.5 mmol of Compound IX, 5 ml of methanol, and 5 ml of ethanol were added into a reaction bottle. Next, after removing moisture and purging nitrogen gas several times, the reaction bottle was heated to 90° C. After reacting for 12 hrs and cooling down to room temperature, the result was extracted three times using dichloromethane and water as the extraction solvent, and the combined organic phase was separated and concentrated, and then purified by column chromatography ((SiO₂, EA/Hexane=1/20), obtaining Organometallic compound I with a yield of 43%. The synthesis pathway of the above reaction was as follows:

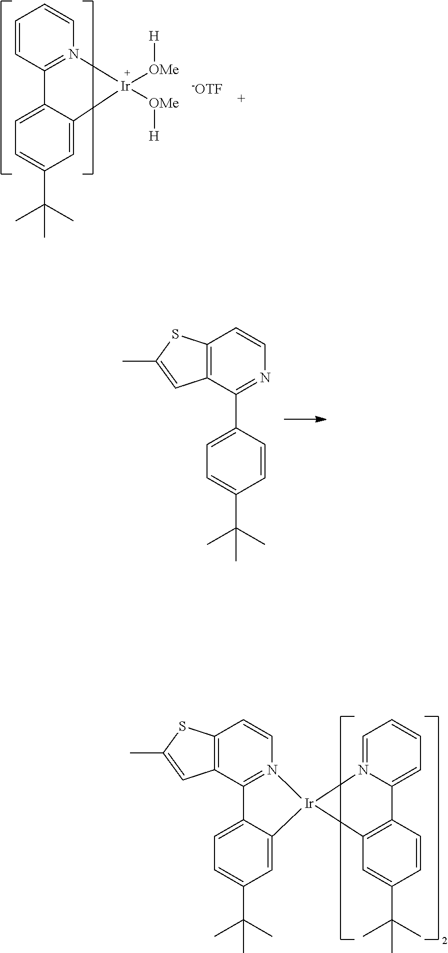

The physical measurement of the Compound I is listed below: ¹H-NMR (500 MHz, CDCl₃, 294 K): 8.03 (d, 1H), 7.92 (s, 1H), 7.74 (t, 2H), 7.53˜7.50 (m, 3H), 7.47˜7.40 (m, 2H), 7.37˜7.35 (m, 2H), 7.14 (d, 1H), 7.04 (s, 1H), 6.98 (dd, 1H), 6.92˜6.88 (m, 3H), 6.80˜6.76 (m, 2H), 6.72˜6.69 (m, 1H), 2.65 (s, 3H), 1.12 (s, 9H), 1.09 (s, 9H), 1.07 (s, 9H).

### Example 10: Preparation of Organometallic Compound J

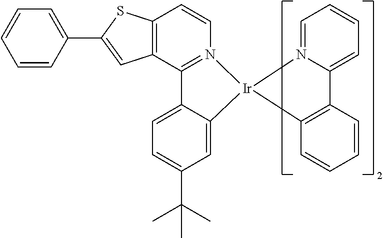

70.9 Mmol of 2-(2-aminoethyl)-5-benzylthiophene and 40 ml of water were added into a reaction bottle. Next, 11 mL of benzoyl chloride (94.7 mmolM) and 45 mL of sodium hydroxide aqueous solution (20%) were dropwisely added into the reaction bottle at 0° C. and subjected to reaction for 12 hrs. Then, the mixture was filtrated. The filter cake was collected, washed with water and hexane, and dried, yielding a white solid. Compound X was obtained with a yield of 68%. The synthesis pathway of the above reaction was as follows:

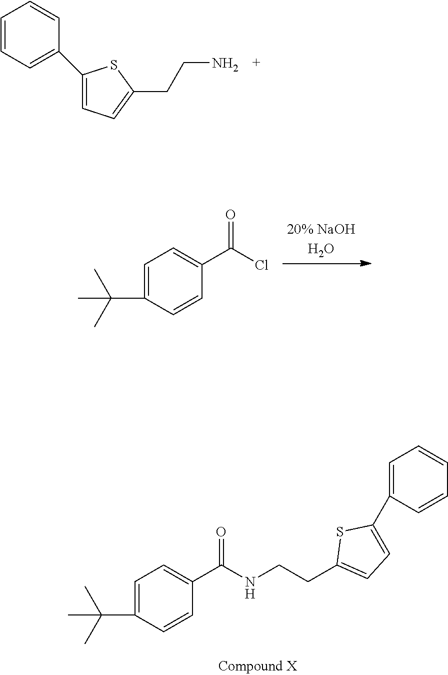

Phosphorus oxychloride (POCl₃, 75 mmol) was dropwisely added at 0° C. to a stirred solution of Compound X (50 mmol) in toluene (50 ml). The reaction was then heated to reflux for 2 hrs (After stopping the stirring, the phase separation occurred. The upper layer was brown liquid and the lower layer was black liquid). After cooling to about 40° C., the reaction mixture was neutralized with saturated sodium hydrogen carbonate (NaHCO₃) aqueous solution, and then the mixture was extracted with ethyl acetate (EA) and water. Next, an organic phase was separated and concentrated, and then purified by column chromatography ((SiO₂, EA/Hexane=1/20). Finally, the result was concentrated and then washed with hexane to form a crystal of 99% purity, obtaining Compound XI with a yield of 65%. The synthesis pathway of the above reaction was as follows:

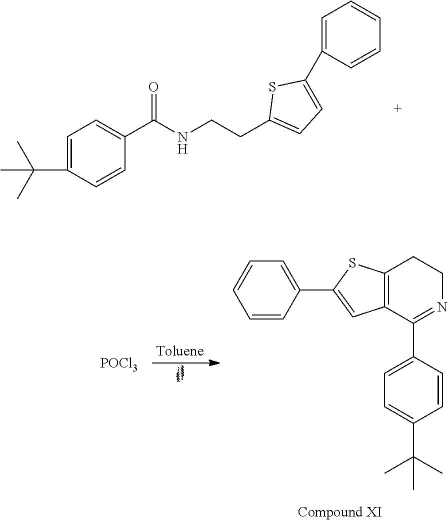 [SMILES: CC(C)(C)c1ccc(C(=O)NCCc2ccc(-c3ccccc3)s2)cc1 ; "POCl3" ; CC(C)(C)c1ccc(C2=NCCc3sc(-c4ccccc4)cc32)cc1]

Next, 50 mmol of Compound XI was dissolved in 100 ml of toluene. After cooling at 0° C., 10 g of palladium 10% on carbon (Pd/C catalyst) was added into the reaction bottle, and was heated to reflux for 2 hrs (using thin layer chromatography (TLC: SiO₂) to confirm completion of the reaction). Next, after removing Pd/C catalyst by filtration, the filtrate was extracted three times using ethyl acetate (EA) and water as the extraction solvent, and an organic phase was separated and concentrated, and then purified by column chromatography (SiO₂, EA/Hexane=1/20). Finally, the result was concentrated and then washed with hexane to form a crystal of 99% purity, obtaining Compound XII with a yield of 92%. The synthesis pathway of the above reaction was as follows:

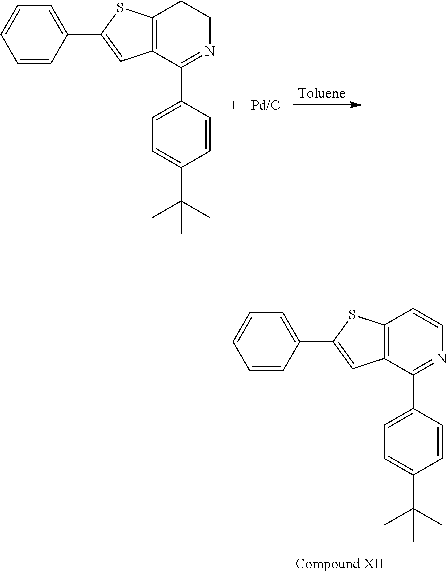 [SMILES: CC(C)(C)c1ccc(C2=NCCc3sc(-c4ccccc4)cc32)cc1 ; CC(C)(C)c1ccc(-c2nccc3sc(-c4ccccc4)cc23)cc1]

Next, 1 mmol of Salt-A, 1.5 mmol of Compound XII, 5 ml of methanol, and 5 ml of ethanol were added into a reaction bottle. Next, after removing moisture and purging nitrogen gas several times, the reaction bottle was heated to 90° C. After reacting for 12 hrs and cooling down to room temperature, the result was extracted three times using dichloromethane and water as the extraction solvent, and the combined organic phase was separated and concentrated, and then purified by column chromatography ((SiO₂, EA/Hexane=1/20), obtaining Organometallic compound J with a yield of 38%. The synthesis pathway of the above reaction was as follows:

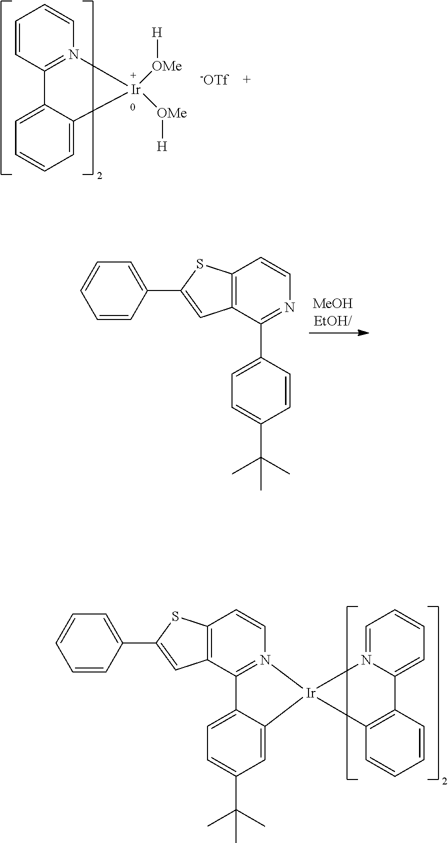

The physical measurement of the Compound J is listed below: ¹H-NMR (500 MHz, CDCl₃, 294 K): 8.46 (s, 1H), 8.14 (d, 1H), 7.88 (d, 1H), 7.84 (d, 1H), 7.73 (d, 2H), 7.64 (dd, 2H), 7.59˜7.52 (m, 3H), 7.48˜7.45 (m, 3H), 7.40˜7.37 (m, 2H), 7.24 (s, 1H), 7.01 (t, 2H), 6.90˜6.75 (m, 8H), 1.11 (s, 9H).

### Example 11: Preparation of Organometallic Compound K

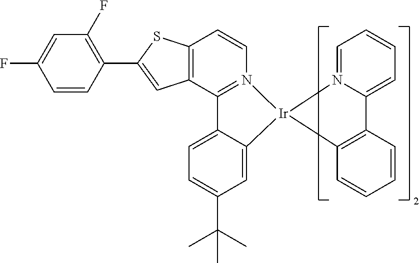

70.9 mmol of 2-(2-aminoethyl)-5-benzylthiophene and 40 ml of water were added into a reaction bottle. Next, 94.7 mmol of 4-tert-Butylbenzoyl chloride and 45 mL of sodium hydroxide aqueous solution (20%) were dropwisely added into the reaction bottle at 0° C. and subjected to reaction for 12 hrs. Then, the mixture was filtrated. The filter cake was collected, washed with water and hexane, and dried, yielding a white solid. Compound XIII was obtained with a yield of 75%. The synthesis pathway of the above reaction was as follows:

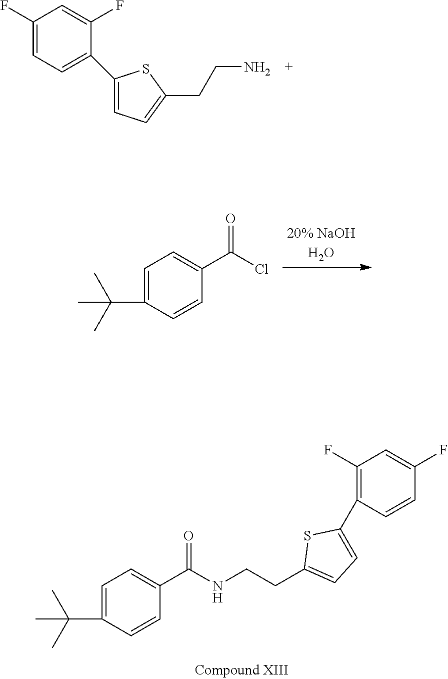

Phosphorus oxychloride (POCl₃, 75 mmol) was dropwisely added at 0° C. to a stirred solution of Compound (XIII) (50 mmol) in toluene (50 ml). The reaction was then heated to reflux for 2 hrs (After stopping the stirring, the phase separation occurred. The upper layer was brown liquid and the lower layer was black liquid). After cooling to about 40°, the reaction mixture was neutralized with saturated sodium hydrogen carbonate (NaHCO₃) aqueous solution, and then the mixture was extracted with ethyl acetate (EA) and water. Next, an organic phase was separated and concentrated, and then purified by column chromatography ((SiO₂, EA/Hexane=1/20). Finally, the result was concentrated and then washed with hexane to form a crystal of 99% purity, obtaining Compound XIV with a yield of 70%. The synthesis pathway of the above reaction was as follows:

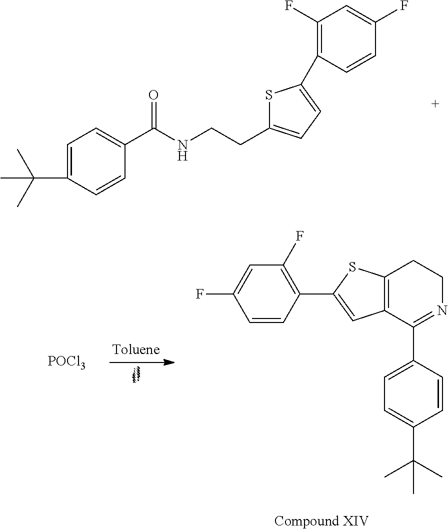 [SMILES: CC(C)(C)c1ccc(C(=O)NCCc2ccc(-c3ccc(F)cc3F)s2)cc1 ; "POCl3" ; CC(C)(C)c1ccc(C2=NCCc3sc(-c4ccc(F)cc4F)cc32)cc1]

Next, 50 mmol of Compound XIV was dissolved in 100 ml of toluene. After cooling at 0° C., 10 g of palladium 10% on carbon (Pd/C catalyst) was added into the reaction bottle, and was heated to reflux for 2 hrs (using thin layer chromatography (TLC: SiO₂) to confirm completion of the reaction). Next, after removing Pd/C catalyst by filtration, the filtrate was extracted three times using ethyl acetate (EA) and water as the extraction solvent, and an organic phase was separated and concentrated, and then purified by column chromatography ((SiO₂, EA/Hexane=1/20). Finally, the result was concentrated and then washed with hexane to form a crystal of 99% purity, obtaining Compound (XV) with a yield of 90%. The synthesis pathway of the above reaction was as follows:

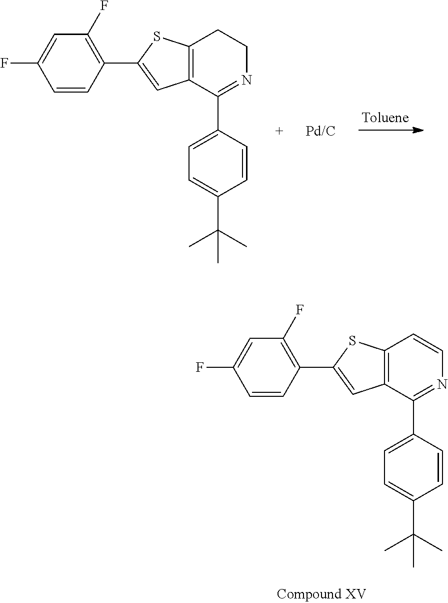 [SMILES: CC(C)(C)c1ccc(C2=NCCc3sc(-c4ccc(F)cc4F)cc32)cc1 ; "Pd/C" ; CC(C)(C)c1ccc(-c2nccc3sc(-c4ccc(F)cc4F)cc23)cc1]

Next, 1 mmol of Salt-A, 1.5 mmol of Compound XV, 5 ml of methanol, and 5 ml of ethanol were added into a reaction bottle. Next, after removing moisture and purging nitrogen gas several times, the reaction bottle was heated to 90° C. After reacting for 12 hrs and cooling down to room temperature, the result was extracted three times using dichloromethane and water as the extraction solvent, and the combined organic phase was separated and concentrated, and then purified by column chromatography ((SiO₂, EA/Hexane=1/20), obtaining Organometallic compound K with a yield of 27%. The synthesis pathway of the above reaction was as follows:

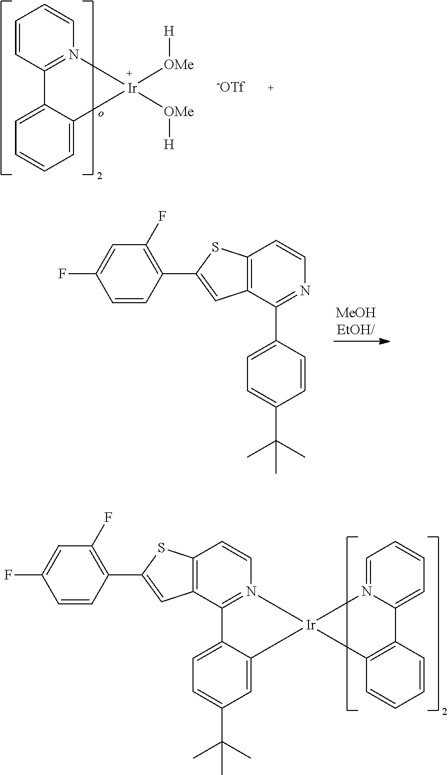

The physical measurement of the Compound K is listed below: ¹H-NMR (500 MHz, CDCl₃, 294 K): 8.57 (s, 1H), 8.10 (d, 1H), 7.90 (d, 1H), 7.89 (d, 1H), 7.67˜7.64 (m, 3H), 7.56˜7.54 (m, 3H), 7.48 (d, 1H), 7.42 (d, 1H), 7.28 (d, 1H), 7.03˜6.99 (m, 4H), 6.90˜6.78 (m, 8H), 1.11 (s, 9H).

### Example 12: Preparation of Organometallic Compound L

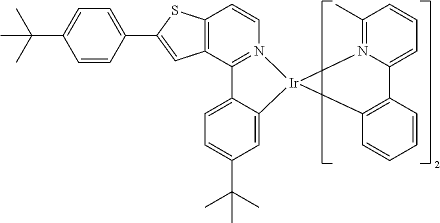

70.9 mmol of 2-(2-aminoethyl)-5-benzylthiophene and 40 ml of water were added into a reaction bottle. Next, 94.7 mmol of 4-tert-Butylbenzoyl chloride and 45 mL of sodium hydroxide aqueous solution (20%) were dropwisely added into the reaction bottle at OTC and subjected to reaction for 12 hours. Then, the mixture was filtrated. The filter cake was collected, washed with water and hexane, and dried, yielding a white solid. Compound XVI was obtained with a yield of 75%. The synthesis pathway of the above reaction was as follows:

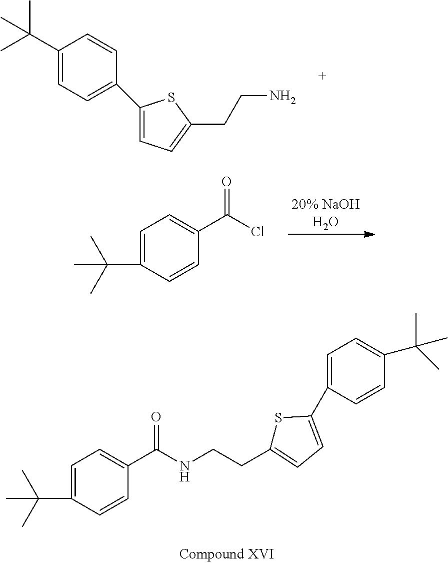 [SMILES: CC(C)(C)c1ccc(-c2ccc(CCN)s2)cc1 ; CC(C)(C)c1ccc(C(=O)Cl)cc1 ; CC(C)(C)c1ccc(C(=O)NCCc2ccc(-c3ccc(C(C)(C)C)cc3)s2)cc1]

Phosphorus oxychloride (POCl₃, 75 mmol) was dropwisely added at 0° C. to a stirred solution of Compound XVI (50 mmol) in toluene (50 ml). The reaction was then heated to reflux for 2 hrs (After stopping the stirring, the phase separation occurred. The upper layer was brown liquid and the lower layer was black liquid). After cooling to about 40° C., the reaction mixture was neutralized with saturated sodium hydrogen carbonate (NaHCO₃) aqueous solution, and then the mixture was extracted with ethyl acetate (EA) and water. Next, an organic phase was separated and concentrated, and then purified by column chromatography ((SiO₂, EA/Hexane=1/20). Finally, the result was concentrated and then washed with hexane to form a crystal of 99% purity, obtaining Compound XVII with a yield of 69%. The synthesis pathway of the above reaction was as follows:

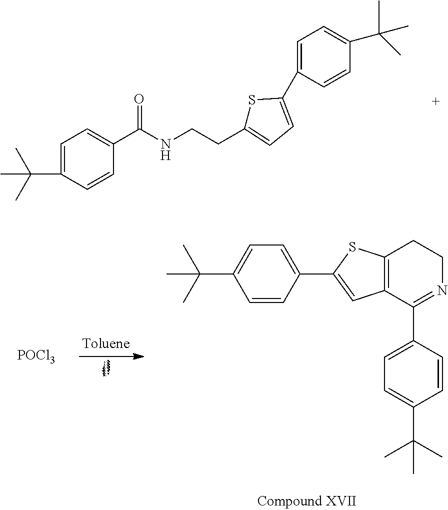

Next, 50 mmol of Compound XVII was dissolved in 100 ml of toluene. After cooling at 0° C., 10 g of palladium 10% on carbon (Pd/C catalyst) was added into the reaction bottle, and was heated to reflux for 2 hrs (using thin layer chromatography (TLC: SiO₂) to confirm completion of the reaction). Next, after removing Pd/C catalyst by filtration, the filtrate was extracted three times using ethyl acetate (EA) and water as the extraction solvent, and an organic phase was separated and concentrated, and then purified by column chromatography ((SiO₂, EA/Hexane=1/20). Finally, the result was concentrated and then washed with hexane to form a crystal of 99% purity, obtaining Compound (XVII) with a yield of 88%. The synthesis pathway of the above reaction was as follows:

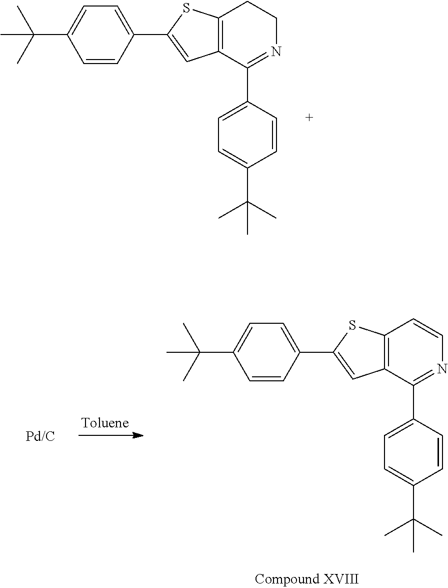

Next, 1 mmol of Salt-B, 1.5 mmol of Compound XVIII, 5 ml of methanol, and 5 ml of ethanol were added into a reaction bottle. Next, after removing moisture and purging nitrogen gas several times, the reaction bottle was heated to 90° C. After reacting for 12 hrs and cooling down to room temperature, the result was extracted three times using dichloromethane and water as the extraction solvent, and the combined organic phase was separated and concentrated, and then purified by column chromatography ((SiO₂, EA/Hexane=1/20), obtaining Organometallic compound L with a yield of 55%. The synthesis pathway of the above reaction was as follows:

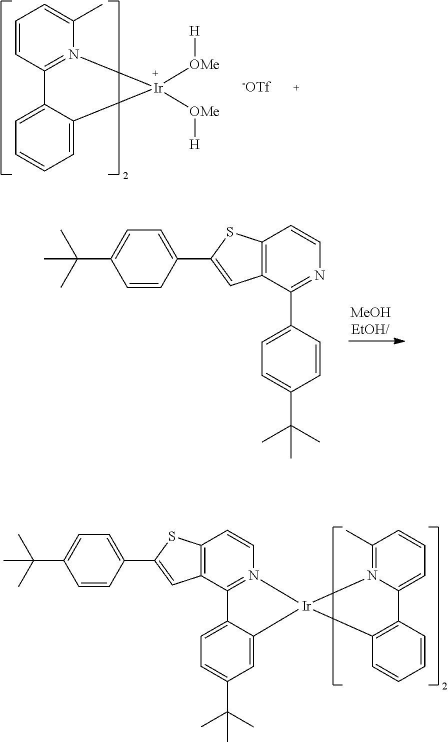

The physical measurement of the Compound L is listed below: ¹H-NMR (500 MHz, CDCl₃, 294 K): 8.37 (s, 1H), 8.03 (d, 1H), 7.83 (d, 2H), 7.73 (d, 1H), 7.65 (d, 2H), 7.59˜7.53 (m, 3H), 7.47 (d, 2H), 7.40 (t, 1H), 7.17 (d, 1H), 6.96 (d, 1H), 6.92˜6.88 (m, 2H), 6.81 (t, 1H), 6.79˜6.78 (m, 2H), 6.67˜6.58 (m, 4H), 2.05 (s, 3H), 1.93 (s, 3H), 1.36 (s, 9H), 1.02 (s, 9H).

### Example 13: Preparation of Organometallic Compound M

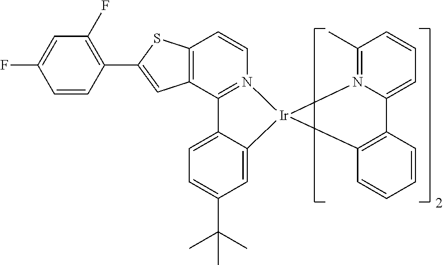

Next, 1 mmol of Salt-B, 1.5 mmol of Compound XV, 5 ml of methanol, and 5 ml of ethanol were added into a reaction bottle. Next, after removing moisture and purging nitrogen gas several times, the reaction bottle was heated to 90° C. After reacting for 12 hrs and cooling down to room temperature, the result was extracted three times using dichloromethane and water as the extraction solvent, and the combined organic phase was separated and concentrated, and then purified by column chromatography ((SiO₂, EA/Hexane=1/20), obtaining Organometallic compound M with a yield of 54%. The synthesis pathway of the above reaction was as follows:

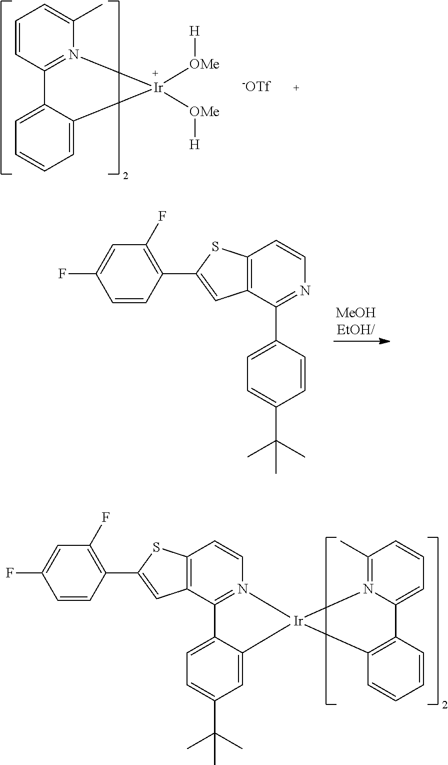

The physical measurement of the Compound M is listed below: ¹H-NMR (500 MHz, CDCl₃, 294 K): 8.52 (s, 1H), 8.01 (d, 1H), 7.83 (d, 2H), 7.74 (d, 1H), 7.68˜7.54 (m, 4H), 7.41 (t, 1H), 7.19 (d, 1H), 7.01˜6.97 (m, 3H), 6.60˜6.91 (m, 2H), 6.80 (t, 1H), 6.78˜6.56 (m, 6H), 2.05 (s, 3H), 1.93 (s, 3H), 1.02 (s, 9H).

### Example 14: Preparation of Organometallic Compound N

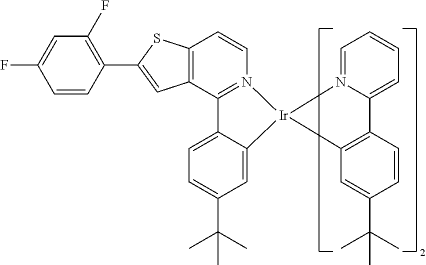

Next, 1 mmol of Salt-C, 1.5 mmol of Compound XV, 5 ml of methanol, and 5 ml of ethanol were added into a reaction bottle. Next, after removing moisture and purging nitrogen gas several times, the reaction bottle was heated to 90° C. After reacting for 12 hrs and cooling down to room temperature, the result was extracted three times using dichloromethane and water as the extraction solvent, and the combined organic phase was separated and concentrated, and then purified by column chromatography ((SiO₂, EA/Hexane=1/20), obtaining Organometallic compound N with a yield of 46%. The synthesis pathway of the above reaction was as follows:

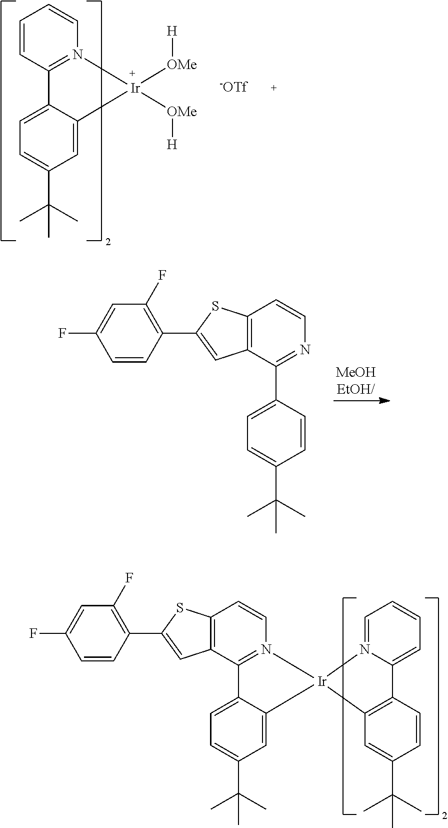

The physical measurement of the Compound N is listed below: ¹H-NMR (500 MHz, CDCl₃, 294 K): 8.54 (s, 1H), 8.09 (d, 1H), 7.77 (d, 1H), 7.73˜7.71 (m, 1H), 7.65˜7.63 (m, 1H), 7.56˜7.37 (m, 71H), 7.15˜7.14 (m, 1H), 7.07 (s, 1H), 7.03 (dd, 1H), 6.96 (t, 2H), 6.93˜6.90 (m, 3H), 6.82˜6.79 (m, 2H), 6.73˜6.70 (m, 1H), 1.13 (s, 9H), 1.09 (s, 9H), 1.06 (s, 9H).

### Example 15: Preparation of Organometallic Compound O

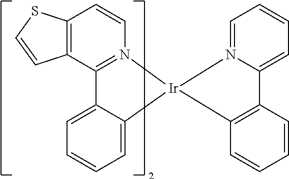

Next, 4.4 mmol of Compound III, and 2 mmol of iridium trichloride (IrCl₃), 75 ml of 2-methoxyethanol, and 25 ml of water were added into the reaction bottle. After removing moisture and purging nitrogen gas several times, the reaction bottle was heated to reflux under a nitrogen atmosphere and kept reacting for 24 hrs. After cooling to room temperature, water was added into the reaction mixture to produce precipitate. Then, the precipitate was filtrated. The filter cake was collected, washed with water and n-hexane, and dried, obtaining Dimer-D. The synthesis pathway of the above reaction was as follows:

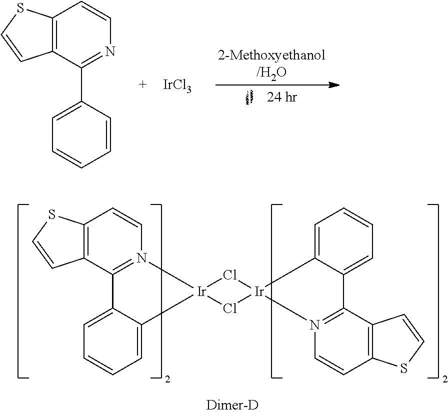

Next, 2.2 mmol of silver trifluoromethane sulfonate (AgOTf) was dissolved in 11 mL of methanol, obtaining an AgOTf-methanol solution. Then, to a stirred solution of 1 mmol of Dimer-D in 10 mL of dichloromethane was added the AgOTf-methanol solution via syringe under nitrogen, and the mixture was stirred for 12 hrs at room temperature. After filtrating for removing sliver chloride and concentrating, Salt-D was obtained. The synthesis pathway of the above reaction was as follows:

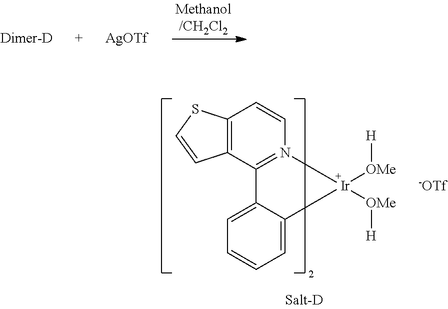

Next, 1 mmol of Salt-D, 1.5 mmol of phenylpyridine, 5 ml of methanol, and 5 ml of ethanol were added into a reaction bottle. Next, after removing moisture and purging nitrogen gas several times, the reaction bottle was heated to 90° C. After reacting for 12 hrs and cooling down to room temperature, the result was extracted three times using dichloromethane and water as the extraction solvent, and the combined organic phase was separated and concentrated, and then purified by column chromatography ((SiO₂, EA/Hexane=1/20), obtaining Organometallic compound O with a yield of 37%. The synthesis pathway of the above reaction was as follows:

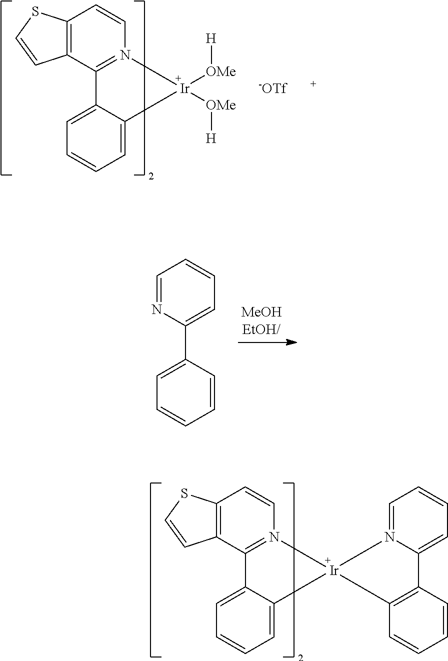

The physical measurement of the Compound O is listed below: 1H-NMR (500 MHz, CDCl3, 294 K): 8.35 (d, 2H), 8.22˜8.20 (m, 2H), 7.89 (d, 1H), 7.66 (d, 1H), 7.62˜7.56 (m, 3H), 7.53˜7.42 (m, 2H), 7.38˜7.35 (m, 2H), 7.31 (d, 1H), 7.05˜6.79 (m, 10H).

### Example 16: Preparation of Organometallic Compound P

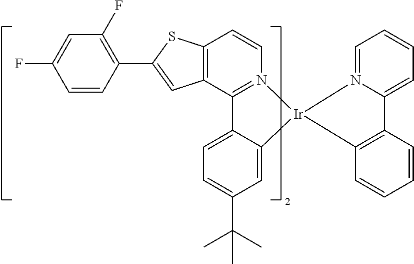

Next, 4.4 mmol of Compound XIV, and 10 mmol of iridium trichloride (IrCl₃), 75 ml of 2-methoxyethanol, and 25 ml of water were added into the reaction bottle. After removing moisture and purging nitrogen gas several times, the reaction bottle was heated to reflux under a nitrogen atmosphere and kept reacting for 24 hrs. After cooling to room temperature, water was added into the reaction mixture to produce precipitate. Then, the precipitate was filtrated. The filter cake was collected, washed with water and n-hexane, and dried, obtaining Dimer-E. The synthesis pathway of the above reaction was as follows:

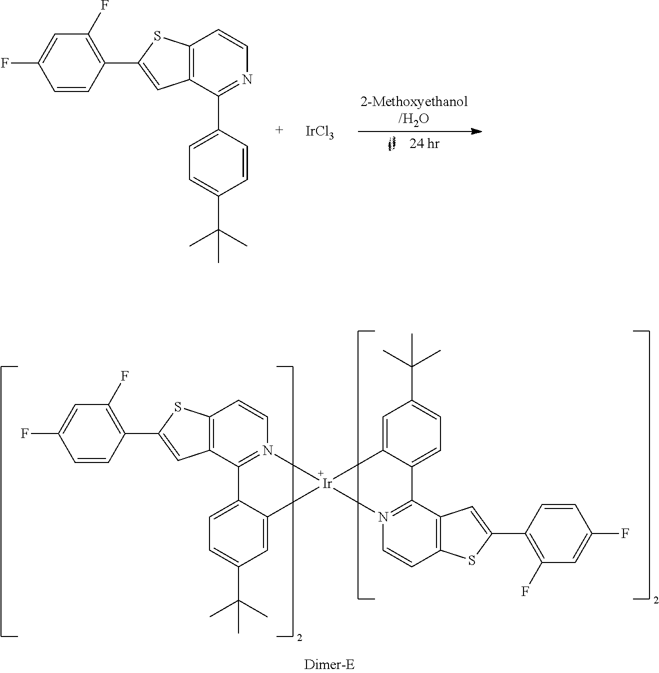

Next, 2.2 mmol of silver trifluoromethane sulfonate (AgOTf) was dissolved in 11 mL of methanol, obtaining an AgOTf-methanol solution. Then, to a stirred solution of 1 mmol of Dimer-E in 10 mL of dichloromethane was added the AgOTf-methanol solution via syringe under nitrogen, and the mixture was stirred for 12 hrs at room temperature. After filtrating for removing sliver chloride and concentrating, Salt-E was obtained. The synthesis pathway of the above reaction was as follows:

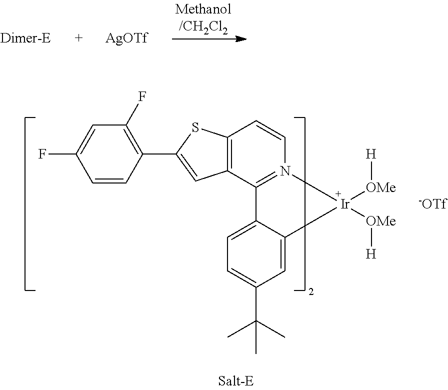

Next, 1 mmol of Salt-E, 1.5 mmol of phenylpyridine, 5 ml of methanol, and 5 ml of ethanol were added into a reaction bottle. Next, after removing moisture and purging nitrogen gas several times, the reaction bottle was heated to 90° C. After reacting for 12 hrs and cooling down to room temperature, the result was extracted three times using dichloromethane and water as the extraction solvent, and the combined organic phase was separated and concentrated, and then purified by column chromatography ((SiO₂, EA/Hexane=1/20), obtaining Organometallic compound P with a yield of 45%. The synthesis pathway of the above reaction was as follows:

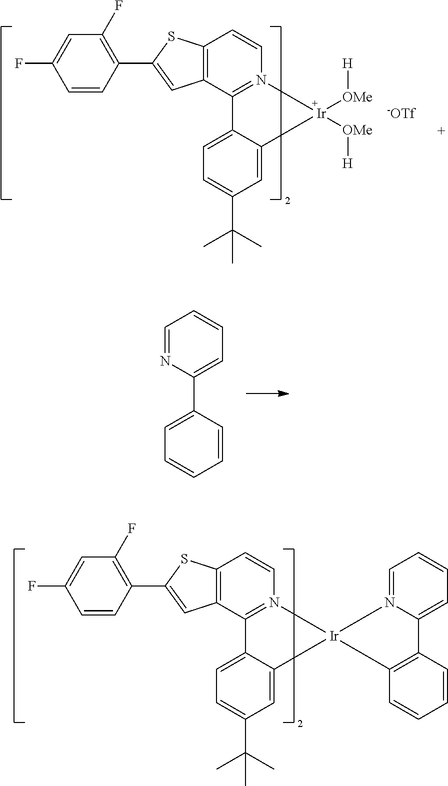

The physical measurement of the Compound P is listed below: ¹H-NMR (500 MHz, CDCl₃, 294 K): 8.58 (d, 2H), 8.12 (t, 2H), 7.88 (d, 1H), 7.71˜7.65 (m, 3H), 7.57 (t, 1H), 7.44 (d, 2H), 7.37 (d, 1H), 7.31 (d, 1H), 7.27 (s, 1H), 7.09 (s, 1H), 7.06˜7.04 (m, 6H), 6.95˜6.91 (m, 5H), 1.14 (s, 9H), 1.09 (s, 9H).

The photoluminescence (PL) spectra of the organometallic compound having a structure of Formula (I) of the disclosure as disclosed in Examples were measured, and the results are shown in Table II.

TABLE II

| | maximum PL | | maximum PL |
|---|---|---|---|
| organometallic | wavelength | organometallic | wavelength |
| compound | (nm) | compound | (nm) |
| A | 558 | B | 548 |
| C | 540 | D | 556 |
| E | 551 | F | 544 |
| G | 557 | H | 555 |
| I | 548 | J | 574 |
| K | 570 | L | 565 |
| M | 570 | N | 572 |
| O | 560 | P | 569 |

Organometallic compounds are important phosphorescent materials or fabrication of OLEDs, iridium(III)-complexes especially. However, not all organometallic compounds are suitable for being purified by a sublimation process. For example, the sublimation yield of the conventional phosphorescent material FIr(pic) (having a structure represented by

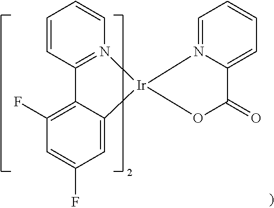

is only about 50%. On the other hand, since the fabrication of OLEDs, iridium(III)-complexes especially. However, not all organometallic compounds are suitable for being purified by a sublimation process. For example, the sublimation yield of the conventional phosphorescent material FIr(pic) (having a structure represented by

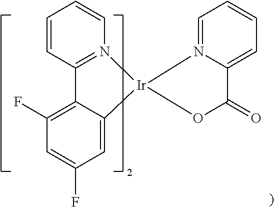

is only about 50%. On the other hand, since the organometallic compounds having Formula (I) of the disclosure have good thermal stability, they are suitable for being purified by a sublimation process (the organometallic compound having Formula (I) of the disclosure has a sublimation yield greater than 80%).

The sublimation temperature and yield of the organometallic compound having a structure of Formula (I) of the disclosure as disclosed in Examples were measured, and the results are shown in Table III.

TABLE III

| organo- | sublimation | | organo- | sublimation | |
|---|---|---|---|---|---|
| metallic | temperature | | metallic | temperature | |
| compound | (° C.) | Yield | compound | (° C.) | yield |
| A | 230 | 82% | B | 230 | 80% |
| C | 235 | 82% | D | 230 | 85% |
| E | 230 | 87% | F | 235 | 85% |
| L | 260 | 81% | M | 265 | 87% |

| | | |
|---|---|---|
| FIr(pic) | 245 | 50% |

### Example 17-26

Preparation of the Organic Light-Emitting Device (1)-(10) (Through Deposition Process)

A glass substrate with a patterned indium tin oxide (ITO) film of 150 nm was provided and then washed with a neutral cleaning agent, acetone, and ethanol with ultrasonic agitation. After drying the substrate with a nitrogen flow, the substrate was subjected to a UV/ozone treatment for 30 minutes. Next, PEDOT (poly(3,4)-ethylendioxythiophen) and PSS (e-polystyrene sulfonate) between TCTA and compound A-P was 100:6-100:8, with a thickness of 15 nm), Next, a TmPyPB (1,3,5-tri[(3-pyridyl)-phen-3-yl]benzene) layer (with a thickness of 42 nm, serving as a hole-block/electron-transport layer), a LiF layer (with a thickness of 0.5 nm), and an Al layer (with a thickness of 120 nm) were subsequently deposited on the light-emitting film under 10-6 torr and packaged, obtaining the organic light-emitting device (1)-(10). The structure of the Oled device (1)-(10) is described in the following:

Oled device (1): ITO (150 nm)/PEDOT:PSS (40 nm)/TAPC (35 nm)/TCTA: compound A (6-8%, 15 nm)/TmPyPB (42 nm)/LiF (0.5 nm)/Al (120 nm).

Oled device (2): ITO (150 m)/PEDOT:PSS (40 nm)/TAPC (35 nm)/TCTA: compound B (6-8%, 15 nm)/TmPyPB (42 nm)/LiF (0.5 nm)/Al (120 nm).

Oled device (3): ITO (150 nm)/PEDOT:PSS (40 nm)/TAPC (35 nm)/TCTA: compound C (6-8%, 15 nm)/TmPyPB (42 nm)/LiF (0.5 nm)/Al (120 nm).

Oled device (4): ITO (150 nm)/PEDOT:PSS (40 nm)/TAPC (35 nm)/TCTA: compound D (6-8%, 15 nm)/TmPyPB (42 nm)/LiF (0.5 nm)/Al (120 nm).

Oled device (5): ITO (150 nm)/PEDOT:PSS (40 nm)/TAPC (35 nm)/TCTA: compound E (6-8%, 15 nm)/TmPyPB (42 nm)/LiF (0.5 nm)/Al (120 nm).

Oled device (6): ITO (150 nm)/PEDOT:PSS (40 nm)/TAPC (35 nm)/TCTA: compound F (6-8%, 15 nm)/TmPyPB (42 nm)/LiF (0.5 nm)/Al (120 nm).

Oled device (7): ITO (150 nm)/PEDOT:PSS (40 nm)/TAPC (35 nm)/TCTA: compound K (6-8%, 15 nm)/TmPyPB (42 nm)/LiF (0.5 nm)/Al (120 nm).

Oled device (8): ITO (150 nm)/PEDOT:PSS (40 nm)/TAPC (35 nm)/TCTA: compound M (6-8%, 15 nm)/TmPyPB (42 nm)/LiF (0.5 nm)/Al (120 nm).

Oled device (9): ITO (150 nm)/PEDOT:PSS (40 nm)/TAPC (35 nm)/TCTA: compound O (6-8%, 15 nm)/TmPyPB (42 nm)/LiF (0.5 nm)/Al (120 nm).

Oled device (10): ITO (150 nm)/PEDOT:PSS (40 nm)/TAPC (35 nm)/TCTA: compound P (6-8%, 15 nm)/TmPyPB (42 nm)/LiF (0.5 nm)/Al (120 nm).

The optical properties including current efficiency (cd/A), power efficiency (m/W), and emission wavelength (nm) of the Oled device (1)-(10) were measured and the results are described in Table 4.

### Comparative Example 1

Preparation of a Conventional Organic Light-Emitting Device (Through Deposition Process)

The preparation of the organic light-emitting device of this comparative example is similar to that of Example 17-30. The distinction there between is that the compound-doping TCTA layer was prepared by doping compound PO-01 into TCTA. The structure of the conventional Oled device is described in the following:

The conventional Oled device: ITO (150 nm)/PEDOT:PSS (40 nm)/TAPC (35 nm)/TCTA: compound PO-01 (having a structure represented by

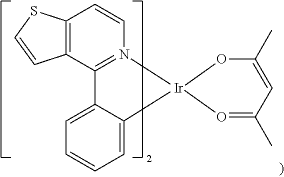

(6-8%, 15 nm)/TmPyPB (42 nm)/LiF (0.5 nm)/Al (120 nm).

The optical properties including current efficiency (cd/A), power efficiency (lm/W), and emission wavelength (nm) of the conventional organic light-emitting device were measured and the results are described in Table 2.

TABLE IV

| | Organo- | current | power | Emission |
|---|---|---|---|---|
| Examples/ | metallic | efficiency | efficiency | wavelength |
| Com. Examples | compounds | (cd/A) | (lm/W) | (nm) |
| Comparative | PO-01 | 65 | 54 | 560 |
| Example 1 | | | | |
| Example 17/ | A | 75 | 67 | 556 |
| OLED device (1) | | | | |
| Example 18/ | B | 78 | 68 | 550 |
| OLED device (2) | | | | |
| Example 19/ | C | 76 | 68 | 544 |
| OLED device (3) | | | | |
| Example 20/ | D | 80 | 67 | 556 |
| OLED device (4) | | | | |
| Example 21/ | E | 78 | 65 | 552 |
| OLED device (5) | | | | |
| Example 22/ | F | 78 | 65 | 544 |
| OLED device (6) | | | | |
| Example 23/ | K | 76 | 66 | 546 |
| OLED device (7) | | | | |
| Example 24/ | M | 80 | 69 | 568 |
| OLED device (8) | | | | |
| Example 25/ | O | 85 | 73 | 564 |
| OLED device (9) | | | | |
| Example 26/ | P | 82 | 75 | 550 |
| OLED device (10) | | | | |

As shown in Table 4, during the formation of the light-emitting devices (1)-(10) via a deposition process, it shows that the organic light-emitting device employing the organometallic compound having the structure of Formula (I) exhibits high luminous efficiency.

It will be clear that various modifications and variations can be made to the disclosed methods and materials. It is intended that the specification and examples be considered as exemplary only, with the true scope of the disclosure being indicated by the following claims and their equivalents.

What is claimed is:

1. An organometallic compound, having a structure of Formula (I): 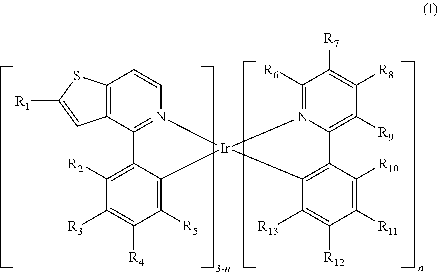
Wherein, R₁ is hydrogen, halogen, C₁₋₁₂ alkyl group, C₁₋₁₂ alkoxy group, amine, C₂₋₆ alkenyl group, C₂₋₆ alkynyl group, C₅₋₁₀ cycloalkyl group, C₃₋₁₂ heteroaryl group, or C₆₋₁₂ aryl group, R₂, R₃, R₄, and R₅ are independently hydrogen, halogen, C₁₋₁₂ alkyl group, C₁₋₁₂ alkoxy group, C₁₋₁₂ fluoroalkyl group, or two adjacent groups of R₂, R₃, R₄, and R₅ are optionally combined with the carbon atoms which they are attached to, to form a cycloalkyl group, or aryl group, R₆, R₇, R₈, R₉, R₁₀, R₁₁, R₁₂ and R₁₃ are independently hydrogen, halogen, C₁₋₁₂ alkyl group, C₁₋₁₂ fluoroalkyl group, or two adjacent groups of R₆, R₇, R₈, R₉, R₁₀, R₁₁, R₁₂ and R₁₃ are optionally combined with the carbon atoms which they are attached to, to form a cycloalkyl group, or aryl group; and n is 1 or 2.

2. The organometallic compound as claimed in claim 1, wherein R¹ is hydrogen, methyl, ethyl, propyl, isopropyl, n-butyl, isobutyl, tert-butyl, pentyl, hexyl, cyclohexyl, a substituted or unsubstituted phenyl group, a substituted or unsubstituted biphenyl group, a substituted or unsubstituted naphthyl group, a substituted or unsubstituted pyridyl group, a substituted or unsubstituted furyl group, a substituted or unsubstituted carbazole group, a substituted or unsubstituted anthryl group, a substituted or unsubstituted phenanthrenyl group, a substituted or unsubstituted imidazolyl group, a substituted or unsubstituted pyrimidinyl group, a substituted or unsubstituted quinolinyl group, a substituted or unsubstituted indolyl group, or a substituted or unsubstituted thiazolyl group.

3. The organometallic compound as claimed in claim 1, wherein each R¹ is

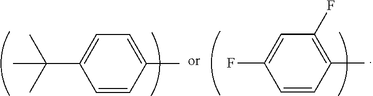

4. The organometallic compound as claimed in claim 1, wherein R², R³, R⁴, and R⁵ are independently hydrogen, fluorine, methyl group, ethyl group, propyl group, isopropyl group, n-butyl group, isobutyl group, tert-butyl group, pentyl group, hexyl group, fluoromethyl, fluoroethyl, methoxy, ethoxy, propoxy, or isopropoxy, or R³ and R⁴ are combined with the carbon atoms which they are attached to, to form a phenyl group.

5. The organometallic compound as claimed in claim 1, wherein R₆, R₇, R₈, R₉, R₁₀, R₁₁, R₁₂ and R₁₃ are independently hydrogen, fluoro, methyl, ethyl, propyl, isopropyl, n-butyl, isobutyl, tert-butyl, pentyl, hexyl, fluoromethyl group, fluoroethyl group, fluoropropyl group, or two adjacent groups of R₇, R₈, R₉, R₁₀, R₁₁ and R₁₂ are optionally combined with the carbon atoms which they are attached to, to form a phenyl group.

6. The organometallic compound as claimed in claim 1, wherein the organometallic compound is 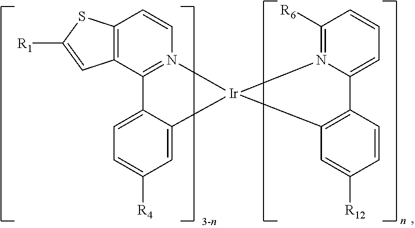
wherein R₁ is hydrogen, halogen, C₁₋₁₂ alkyl group, C₁₋₁₂ alkoxy group, or a substituted or unsubstituted phenyl group; R₄, R₆ and R₁₂ are independently hydrogen, or C₁₋₁₂ alkyl group; and n is 1 or 2.

7. The organometallic compound as claimed in claim 1, wherein the organometallic compound is 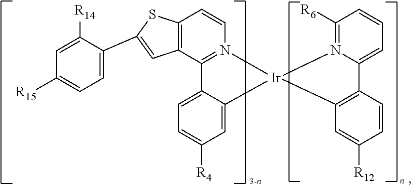
wherein R₁₄ and R₁₅ are independently hydrogen, halogen, or C₁₋₁₂ alkyl group, R₄, R₆ and R₁₂ are independently hydrogen, or C₁₋₁₂ alkyl group; and n is 1 or 2.

8. An organic light-emitting device, comprising:
a pair of electrodes; and
an organic light-emitting element, disposed between the electrodes, wherein the organic light-emitting element comprises the organometallic compound claimed in claim 1.
